(19) United States
(12) Patent Application Publication
(10) Pub. No.: US 2017/0117914 A1
(43) Pub. Date: Apr. 27, 2017

(54) METHOD AND APPARATUS FOR PROVIDING DIGITAL BACKGROUND CALIBRATION FOR MISMATCHES IN M-CHANNEL TIME-INTERLEVED ADCS (TI-ADCS)

(71) Applicant: Industry-Academic Cooperation Foundation, Chosun University, Gwangju (KR)

(72) Inventor: Goang Seog CHOI, Seongnam-si (KR)

(21) Appl. No.: 15/279,417

(22) Filed: Sep. 28, 2016

(30) Foreign Application Priority Data
Oct. 23, 2015 (KR) 10-2015-0147665
Dec. 22, 2015 (KR) 10-2015-0184009

(51) Int. Cl. H03M 1/10; H03M 1/12

(52) U.S. Cl. CPC H03M 1/1023; H03M 1/1245

(57) ABSTRACT

The present invention relates to a method and apparatus for providing digital background calibration for mismatches in M-channel time-interleaved ADCs(TI-ADCs), more specifically providing a pure digital blind calibration technique for offset mismatch, gain mismatch and time mismatch, which are essentially incurred by utilizing a time-interleaved analog-digital converter in systems having to process data with high speeds. Wherein the offset mismatch and gain mismatch are corrected based on statistical characteristics of the digital signals which are sampled and outputted in channel by channel, and the time mismatch is corrected based on a derivative filter and a delay filter. Thereby the present invention relating to a method and apparatus for digital background calibration enables the hardware complexity to be reduced and the efficiency of hardware resource to be increased. The pure digital background calibration of mismatches base on addition, subtraction and multiplication operations is also independent of foundaries and processes, and significantly reduces the design complexity.

### BACKGROUND

High speed analog to digital converters utilized in high speed data processing systems, which are called as ADCs hereinafter, are an essential part of modern communication systems. These systems do not only require high speed data conversion but also require high resolution and low power solutions. Especially with advancements in communication technologies and their applications, existing single cutting-edge ADC, which converts analog signal to digital signal, may be insufficient to meet the requirements with respect to high speed, high precision and low power consumption.

Many technologies are being developed and used for resolving the above problems. Firstly, time interleaved ADC technology is one of the solutions that offer an answer for such systems that combine several existing parallel operating slower single ADCs. In addition, many techniques for solving the above problems have been developed and used. One of the key solutions is a TI-ADC, which offers an answer for such a system by combining a plurality of parallel operating single slower ADCs.

The above TI-ADCs to which pipeline architecture is applied for overcoming disadvantages of the slower ADCs and the slower speed sub ADCs are connected in parallel, take advantages of high speed conversion of analog signal into digital signal as well as high resolution data processing.

The architecture of the time interleaved ADC(TI-ADC) consists of M parallel identical ADCs having fs/M sampling rates in order to obtain overall sampling rate fs. In addition, in the TI-ADC, each converter operates at sampling period M*Ts while sampling space of Ts exists between two consecutive converters. Wherein, Ts means the overall sampling period. Thus, there are advantages that efficiency and sampling accuracy are increased because of reduction in sampling rate required by each ADC by the factor of M resulting in low power consumption.

However, since TI-ADCs adopt time-interleaving architecture, the offset mismatch, gain mismatch and time mismatch can occur between channels. The mismatches can cause the signals to be distorted by coupling of aliased version and spurious tone of input signals. That is, while digital samples of the analog signal among plurality of channels being comprised in a TI-ADC have to the same gain and sampling time, the fact that the gain and sampling time are different between plurality of channels in reality causes mismatches, which reduce the overall performance of the sub ADCs.

Although time-interleaved ADC architecture overcomes the shortcomings of single high speed ADC system but it introduces extra challenges in form of mismatches. That is, in ideal scenario, M parallel operating ADCs (channels) should have identical gain and sampling time between M channels, but in practice the fact that neither gain nor sampling time between ADCs are the same, causes mismatches due to component mismatch and timing jitter. The mismatches degrade the performance of system significantly, and thus they need to be rectified by proper estimation and correction with two possibilities, either in analog domain or in digital domain. The prior arts of rectifying mismatches are as described in Y. C. Jenq, “Digital spectra of nonuniformly sampled signals: fundamentals and high-speed waveform digitizers,” IEEE Trans. Instrum. Meas., vol. 37, no. 3, pp. 245-251, June 1988, A. Petraglia and S. K. Mitra, “Analysis of mismatch effects among A/D converters in time-interleaved waveform digitizers,” IEEE Trans. Instrum. Meas., vol. 40, no. 5, pp. 831-835, October 1991, and N. Kurosawa, H. Kobayashi, K. Maruyama, H. Sugawara, and K. kobayashi, “Explicit analyses of channel mismatch effects in time-interleaved ADC systems,” IEEE Trans. Circuits Syst. I. Fundam. Theory Appl., vol. 48, no. 3, pp. 261-271, March 2001.

Analog and mixed signal techniques are proposed for gain and sample time mismatch correction in A. Haftbaradaran and K. W. Martin, “A background sample-time error calibration technique using random data for wide-band high-resolution time-interleaved ADCs,” IEEE Trans. Circuits Syst. II, Exp. Briefs, vol. 55, no. 3, March 2008, and M. El-Chammas and B. Murmann, “A 12 GS/s 81-mW 5-bit time-interleaved flash ADC with background timing skew calibration,” IEEE J. Solid-State Circuits, vol. 46, no. 4, pp. 838-847, April 2011.

Moreover, in the above analog and mixed signal technologies, the correction of time mismatch error is accomplished by adjusting a capacitance of varactors to calibrate delay of a clock path, specifically for time skew calibration. However, it limits the performance of ADC because of certain variations in supply voltage, temperature, thermal noise or the combinations thereof.

Alternatively, there is a digital domain correction or blind calibration method as an alternative method. The method is preferable because periodically but non-uniformly sampled signal produced by TI-ADC are estimated for errors using digital filter banks (H. Johansson and P. Lowenborg, “Reconstruction of nonuniformly sampled bandlimited signals by means of digital fractional delay filters,” IEEE Trans. Signal Process., vol. 50, no. 11, pp. 2757-2767, November 2002, and R. S. Prendergast, B. C. Levy, and P. J. Hurst, “Reconstruction of bandlimited periodic nonuniformly sampled signals through multirate filter banks,” IEEE Trans. Circuits Syst. I, Fundam. Theory Appl., vol. 51, no. 8, pp. 1612-1622, August 2004) for time calibration and using statistical properties for gain and offset (K. Yang, S. Tian, P. Ye, P. Zhang and Y. Zheng, “A statistic-based calibration method for TI-ADC system,” Mathematical Problems in Engineering, Volume 2015, Hindawi Publishing Corporation.).

However, the above digital domain correction or blind correction method has a problem in that hardware complexity is significantly increased and many hardware resources are consumed because look-up tables should be prepared for filter coefficients calculation and the filter coefficients should always be calculated.

In addition, many techniques have been proposed to estimate and correct mismatches in TI-ADCs.

Firstly, a blind calibration method proposed in R. S. Prendergast, B. C. Levy, and P. J. Hurst (“Reconstruction of bandlimited periodic nonuniformly sampled signals through multirate filter banks” IEEE Trans. Circuits Syst. I, Fundam. Theory Appl., vol. 51, no. 8, pp. 1612-1622, August 2004) calibrates time mismatches by using multi-rate filter-bank structure. In addition, the non-uniform sampled signal is sampled by using analysis bank and the uniformly sampled signal is reconstructed by using synthesis bank. In addition, calibration technique proposed in C. H. Law, P. J. Hurst, and S. H. Lewis (“A four-channel time-interleaved ADC with digital calibration of interchannel timing and memory errors,” IEEE J. Solid-State Circuits, vol. 45. no. 10. pp. 2091-2103, October 2010) is based on multichannel filtering for mismatches which is efficient than filter bank methods and convenient in hardware point of view.

In the method proposed by J. A. McNeill, C. David, M. Coln, and R. Croughwell (“Split ADC′ calibration for all-digital correction of time-interleaved ADC errors,” IEEE Trans. Circuits Syst. II, Exp. Briefs, vol. 56, no. 5, pp. 344-348, May 2009), offset, gain and time mismatches are investigated and corrected by using LMS filters in split ADC architecture where first-order Taylor expansion is employed for approximation of time delay while three tap FIR filter is used to calculate first order derivative.

In the method proposed by J. Matsuno, T. Yamaji, M. Furuta, and T. Itakura (“All-digital background calibration technique for time-interleaved ADC using pseudo aliasing signal,” IEEE Trans. Circuits Syst. I, Reg. Papers, vol. 60, no. 5, pp. 1113-1121, May 2013), gain and time mismatches are calibrated by using pseudo aliasing signals instead of using filter banks.

The above prior arts utilize Hadamard transform expansion for more than two channels and have advantages of reducing the circuit area. However, the above pseudo aliasing method only uses one derivative filter, but it utilized feed-back signals and notch filters for estimation of gain and time mismatches, which takes disadvantages of increasing its complexity. Moreover, the proposed techniques mentioned above, specifically exploiting adaptive filter methods, require large area because of adjustment of dynamic range of filters with ADCs. Besides that, disadvantages that filter coefficients need to be calculated or need to be stored in LUTs should be taken.

Many prior arts techniques using filter banks require M−1 filters for M channel TI-ADC, thus it takes disadvantages of increasing the area and complexity of the system. It refers to Y. C. Lim, Y. X. Zou, J. W. Lee, and S. C. Chan, “Time-interleaved analog-to-digital converter (TI-ADC) compensation using multichannel filters,” IEEE Trans. Circuits Syst. I, Reg. Papers, vol. 56, no. 10, pp. 2234-2247, October 2009. In addition, in the prior art proposed by V. Divi and G. Women (“Blind calibration of timing skew in time-interleaved analog-to-digital converters,” IEEE J. Sel. Topics Signal Process., vol. 3, no. 3, pp. 509-522, June 2009), time skew calibration is proposed using one FIR filter that increases it feasibility for implementation because of less complexity.

Several inventors have proposed blind compensation techniques by S. Huang and B. C. Levy, (“Blind calibration of timing offsets for four-channel time-interleaved ADCs,” IEEE Trans. Circuits Syst. I, Reg. Papers, vol. 54, no. 4, pp: 863-876, June 2007). These blind correction methods do not require estimation of time mismatch errors and directly apply the calibration algorithms. However, the above blind compensation techniques have disadvantages of being considered as less accurate, in general, and considered as complex in computations.

Therefore, the present invention provides a blind calibration technique that is computationally efficient, low in complexity and accurate for offset, gain and time mismatches. The present invention is based on statistical properties of signals for offset and gain calibration where average of channels are calculated and later used as reference channel. Time skew calibration is based on one derivative and one fractional delay filter that make it feasible for area and power sensitive applications. The design challenge is to propose simple, precise and efficient technique to counter the concerns of complexity, robustness and performance. Besides the efficiency and performance, the proposed algorithm is feasible for hardware specifically for two main reasons: (i) only one FIR filter and fractional delay filter are required for time skew calibration having fixed coefficients which eliminate the need for LUTs and adaptive calculations. (ii) For offset and gain calibration, only additions, subtractions and shift operations are required. The performance of technique is verified through computer simulations and hardware model for testing purpose for 8-channel TI-ADCs.

In addition, the present invention provides a digital background calibration apparatus for mismatches in M-channel TI-ADCs, in which offset mismatch and gain mismatch generated by using TI-ADCs in high performance data processing systems are corrected based on statistical characteristics (especially mean of target signals and variance of samples), and time mismatch is corrected based on FIR filter, and thereby reducing the hardware complexity and increasing the efficiency of hardware resource.

Hereinafter the prior arts technologies existing in the technical area of the present invention are reviewed and then the technical differences and discriminatory achievements comparing with the above prior arts technologies are described.

Firstly, Korean patent registration No. 1461784 (2014 Nov. 7) relates to analog to digital converter, the calibration circuits and the calibrating method thereof, especially to a combiner integrating digital signals being outputted from a plurality of channels consisting of TI-ADC, an analog-to-digital converter calibrating time mismatch being included in the digital signal by embedding an adaptive filter between the channel and the combiner, the calibrating circuits, and the calibrating method.

This prior art is similar to the present invention in that both of them relate to the calibration of time mismatch occurred in the digital signals converted by TI-ADCs. However, the prior art requires large hardware area caused by the adjustments of the dynamic range of a plurality of adaptive filters which is used for correcting time mismatches and a plurality of LUT (look-up table) for ever-calculating and storing filter coefficients. And thus the prior art also fails to suggest the calibrating method of offset mismatch and gain mismatch occurred by the TI-ADCs.

Contrary, the present invention can calibrate offset mismatch and gain mismatch based on the statistical characteristics of the digital signals outputted from TI-ADCs, as well as time mismatch through digital FIR filter. The present invention is effective for minimizing hardware resources and being capable of high speed digital processing.

Moreover, Korean patent publication No. 2015-0029087 (2015 Mar. 18) relates to an analog-to-digital converter and the calibration method thereof, in more details calibrates the offsets of the analog-to-digital converter by sequentially controlling the magnitude of the signals applied to the analog-to-digital converter and analyzing the comparison results of the comparator outputted based on the sequentially controlled signals.

This prior art is similar to the present invention in that both of them perform the calibration of offset mismatch occurred in the analog-to-digital converter, however the present invention corrects the gain mismatch and time mismatch, as well as offset mismatch based on adder, subtractor and multiplier. The prior art fails to suggest the technical features with respect to dramatically reducing the time for calibration.

### SUMMARY

The present invention is composed for resolving the above problems, and it is objective to provide a method and apparatus performing effective calculation for estimation and correction of error, reducing the hardware complexity for the calculation and accurately correcting offset mismatch, gain mismatch and time mismatch by the techniques that the offset error and gain error are corrected by the mean of the samples for each channel through the calculation of the mean based on statistical characteristics of the signals in each channel, and the timing delay correction is performed by using a derivative filter and a micro delay filter.

It is objective for the present invention to provide an apparatus for digital background calibration of mismatches which is effective in calculation and minimizes the complexity of hardware design by estimating and correcting offset mismatch and gain mismatch occurred in TI-ADCs based on the statistical characteristics in the digital signals.

It is objective for the present invention to provide an apparatus for digital background calibration of mismatches which significantly reduces the time for the calibration of the mismatches and minimizes the hardware resources as well, by calibrating offset mismatch, gain mismatch and time mismatch based on addition, subtraction and shift arithmetic operations.

In accordance with an embodiment of the present invention, a method for digital background calibration for mismatches in TI-ADC channels: converting input analog signals to digital samples in each channel of time interleaved plurality of channels; performing blind background calibration for offset and gain mismatches of the digital samples for the converted plurality of channels; multiplexing digital samples for a plurality of blind background calibrated channels for the offset and gain; and calibrating time mismatch for the multiplexed digital samples.

In addition, performing the blind background calibration for the offset mismatch further comprises: estimating the offset of reference channel by the mean value of samples outputted from the plurality of channels; estimating the offset of each channel by the mean value of samples for each plurality of channels; calculating offset error for each channel by calculating the difference value between the estimated offset for each channel and the offset of the reference channel; and calibrating the offset of the samples for each channel by subtracting the calculated error for each channel from samples for each channel.

In addition, performing the blind background calibration for the gain mismatch further comprises: estimating the average power of reference channel by the mean square value for offset calibrated samples for a plurality of all channels; estimating the average power for each channel by the mean square value for the samples of each offset calibrated channel; calculating the error for the gain of the first channel by dividing the average power of the estimated first channel by the average power of the reference channel; calculating the error for the gain of each remained channel by dividing the average power of each remained channel by the average power of the estimated first channel; and calibrating the gain of the samples for each channel by dividing the samples of each offset calibrated channel by the error for the gain of the each calculated channel.

In addition, calibrating the time mismatch further comprises: calculating impulse response by using a derivative (or differential) filter for the multiplexed digital samples; convolving the impulse response with the multiplexed digital samples; calculating time delay by dividing the average value multiplying the convolved result by the multiplexed digital sample by mean square value of the convolved result; calibrating time error by multiplying calculated time delay by the convolved result; and calibrating the time delay by subtracting the calculated time error from the multiplexed digital sample.

In addition, calibrating the time mismatch further comprises: calibrating phase and amplitude of the digital sample by using micro delay filter and scaling factor for the time delay calibrated digital sample.

Moreover, in accordance with an embodiment of the present invention, an apparatus for digital background calibration for mismatches in TI-ADC channels: comprises an ADC bank converting input analog signals to digital samples in each channel of time interleaved plurality of channels; a blind background calibrator performing blind background calibration for offset and gain mismatches of the digital samples for the converted plurality of channels; a multiplexer multiplexing digital samples for a plurality of blind background calibrated channels calibrated in the blind background calibrator for the offset and gain mismatches; and a time mismatch calibrator calibrating time delay for the multiplexed digital samples in the multiplexer.

In addition, the blind background calibrator further comprises: a reference channel estimator estimating the offset of reference channel by the mean value of samples outputted from the plurality of channels; an individual channel estimator estimating the offset of each channel by the mean value of samples for each plurality of channels; an error calculator calculating offset error for each channel by calculating the difference value between the estimated offset for each channel and the offset of the reference channel; and a channel error calibrator calibrating the offset of the samples for each channel by subtracting the calculated error for each channel from samples for each channel.

In addition, the reference channel estimator further comprises estimating the average power of reference channel by the mean square value for offset calibrated samples for a plurality of all channels; the individual channel estimator further comprises estimating the average power for each channel by the mean square value for the samples of each offset calibrated channel; the error estimator further comprises calculating the error for the gain of the first channel by dividing the average power of the estimated first channel by the average power of the reference channel, and calculating the error for the gain of each remained channel by dividing the average power of each remained channel by the average power of the estimated first channel; and the channel error calibrator further comprises calibrating the gain of the samples for each channel by dividing the samples of each offset calibrated channel by the error for the gain of each calculated channel.

In addition, the time mismatch calibrator further comprises: calculating impulse response by using a derivative (or differential) filter for the multiplexed digital samples; convolving the impulse response with the multiplexed digital samples; calculating time delay by dividing the average value multiplying the convolved result by the multiplexed digital sample by mean square value of the convolved result; calibrating time error by multiplying calculated time delay by the convolved result; and calibrating the time delay by subtracting the calculated time error from the multiplexed digital sample.

In addition, the time mismatch calibrator further comprises: an error scalier comprises calibrating phase and amplitude of the digital sample by using micro delay filter and scaling factor for the time delay calibrated digital sample.

Moreover, in accordance with an embodiment of the present invention, an apparatus of digital background calibration for mismatches in time interleaved ADCs (TI-ADCs) comprising: an offset mismatch calibrator configured to calibrate offset mismatch for the result of TI-ADC with at least more than two channels and a gain mismatch calibrator coupled to the offset mismatch calibrator and configured to calibrate gain mismatch for the offset calibrated digital sample.

In addition, the apparatus further comprising: a smoothening calibrator configured to calibrate spike (extra high frequency tone) occurring in the course of calibrating the gain mismatch and a time mismatch calibrator coupled to the smoother and configured to calibrate time mismatch for the spike calibrated digital sample.

In addition, the offset mismatch calibrator further comprising: an offset buffer configured to store the digital sample for a plurality of channels, a reference channel offset estimator coupled to the offset buffer and configured to estimate offset of reference channel by calculating the average value for the sum of digital samples outputted from the offset buffer, and an individual channel offset estimator coupled to the offset buffer and configured to estimate offset of individual channel by calculating the average value of digital samples for a plurality of channels outputted from the offset buffer.

In addition, the offset mismatch calibrator further configured to: calculate offset mismatch for each channel by calculating the difference value between the offset of the estimated individual channel and the offset of the reference channel, and calibrate offset mismatch for the digital sample of each channel by subtracting the calculated offset mismatch for each channel from the plurality of digital samples for each channel.

In addition, the gain mismatch calibrator further configured to: calculate the quotient by dividing the average value of the first channel among the plurality of channels by the average value of the reference channel, calibrate the gain mismatch for the digital samples of the first channel by multiplying the digital sample of the first channel by the calculated quotient, calculate the quotient for each channel by dividing the average value for each remained channel excepting for the first channel by the average value of the first channel, and calibrate the gain mismatch of the digital samples for each channel by multiplying the digital samples for each channel by the quotient of each channel.

In addition, the smoothening calibrator further configured to: calculate the average value for the reference channel by averaging the sum of the digital samples for the plurality of channels outputted from the smoothening buffer, which stores the digital samples for the gain calibrated plurality of channels, and calculate the average value of each channel by averaging the sum of the digital samples for each channel outputted from the smoothening buffer.

In addition, the smoothening calibrator further configured to: calculate the spike error for each channel by calculating the difference value between the average value of the calculated average value for each channel and the average value of the reference channel, and calibrate the spike error for the digital samples of each channel by subtracting the calculated spike error for each channel from the digital samples of each channel.

In addition, the time mismatch calibrator further comprising: an input buffer configured to store by channel the spike error calculated digital samples for the plurality of channels, an FIR filter configured to calibrate time delay mismatch for the digital samples, and an output buffer configured to output the digital samples outputted from the FIR filter.

In addition, the FIR filter configured to comprise by each channel a first order FIR low pass filter for the digital samples of the plurality of channels.

The present invention relates to a method and apparatus for providing digital background calibration for mismatches in time-interleaved ADCs channels, performing time mismatch calibration by using only a single derivative filter with fixed coefficients and a micro delay filter, thereby being not necessary to calculate the fixed coefficients or have LUTs for storing the fixed coefficients, which is different from the prior arts, performing only addition, subtraction and shift operations, and thus being effective for calculation, reducing hardware complexity, significantly reducing the time for time delay calibration.

In addition, the present invention calibrates gain mismatch of the first channel by using the reference of the entire channels for the gain mismatch calibration, calibrates the mismatch for the remained plurality of channels with the reference of the first channel for the remained plurality of channels, and thus being effective for accurately calibrating the gain mismatch, as compared to the prior arts ignoring the mismatch of the first channel.

In addition, the present invention calibrates offset mismatch and gain mismatch occurred in TI-ADCs by using statistical characteristics of the digital signals outputted from TI-ADC and calibrates time mismatch by using an FIR filter with fixed filter coefficients, and thus being effective for significantly decreasing the complexity for hardware design and increasing the efficiency for hardware resources.

### BRIEF DESCRIPTION OF THE DRAWINGS

For more complete understanding of this disclosure, reference is now made to the following brief description, taken in connection with the accompanying drawings and detailed description.

FIG. 1 is a block diagram showing a simplified configuration of M-channel TI-ADCs in accordance with a prior art.

FIG. 2 is a block diagram showing a configuration of a digital background calibration apparatus for mismatch in M-channel TI-ADCs in accordance with the preferred embodiment of the present invention.

FIG. 3 is a block diagram showing a configuration of a blind background calibrator of the digital background calibration apparatus for mismatch in M-channel TI-ADCs in accordance with the preferred embodiment of the present invention.

FIG. 4 is a block diagram showing a configuration of a time mismatch calibrator of the digital background calibration apparatus in M-channel TI-ADCs in accordance with the preferred embodiment of the present invention.

FIG. 5 shows a sampling error caused by time skew in accordance with the preferred embodiment of the present invention.

FIG. 6 is a block diagram showing a configuration of time error calibrator of time mismatch calibrator in accordance with the preferred embodiment of the present invention.

FIG. 7 is a block diagram showing a configuration of time skew error calibrator of time mismatch calibrator in accordance with the preferred embodiment of the present invention.

FIG. 8 is an exemplary view showing as a graph of an output spectrum of 8-channel TI-ADCs in accordance with the preferred embodiment of the present invention.

FIG. 9 is an exemplary view showing a change of SNDR of a correction before and after the correction of wideband signal in accordance with the preferred embodiment of the present invention.

FIG. 10 is an exemplary view showing a change of SNDR value according to the number of filter tabs in accordance with the preferred embodiment of the present invention.

FIG. 11 is a flow diagram showing a procedure of the digital background calibration method for mismatch in TI-ADCs in accordance with the preferred embodiment of the present invention.

FIG. 12 is an exemplary view briefly showing a fundamental structure of TI-ADCs and an apparatus for calibrating mismatch in accordance with the preferred embodiment of the prior art.

FIG. 13 is a black diagram showing a digital background calibration apparatus for mismatch in M-channel TI-ADCs in accordance with the preferred embodiment of the present invention.

FIG. 14 is a black diagram showing an offset mismatch calibrator in accordance with the preferred embodiment of the present invention.

FIG. 15 is a black diagram showing an offset buffer in accordance with the preferred embodiment of the present invention.

FIG. 16 is an exemplary view showing a state machine of the control logic for an offset mismatch calibrator in accordance with the preferred embodiment of the present invention.

FIG. 17 is a flow diagram showing procedures performing read and write operations according to the logic of offset buffer in accordance with the preferred embodiment of the present invention.

FIG. 18 and FIG. 19 are block diagrams showing a reference channel offset estimator estimating the offset of reference channel in the offset mismatch calibrator in accordance with the preferred embodiment of the present invention.

FIG. 20 is a block diagram showing a reference channel offset estimator in the offset mismatch calibrator in accordance with the preferred embodiment of the present invention.

FIG. 21 is a block diagram showing a gain mismatch calibrator in accordance with the preferred embodiment of the present invention.

FIG. 22 is an exemplary view showing a state machine of the control logic for the gain mismatch calibrator in accordance with the preferred embodiment of the present invention.

FIG. 23 is a flow diagram showing procedures performing read and write operations according to the gain buffer control logic in accordance with the preferred embodiment of the present invention.

FIG. 24 is a block diagram showing a square calculator in the gain mismatch calibrator in accordance with the preferred embodiment of the present invention.

FIG. 25 and FIG. 26 are block diagrams showing an individual channel average value estimator in the gain mismatch calibrator in accordance with the preferred embodiment of the present invention.

FIG. 27 is a block diagram showing a reference channel average value estimator in the gain mismatch calibrator in accordance with the preferred embodiment of the present invention.

FIG. 28 is a block diagram showing a divider calculator in the gain mismatch calibrator in accordance with the preferred embodiment of the present invention.

FIG. 29 is a block diagram showing the overall structure of the gain mismatch calibrator in accordance with the preferred embodiment of the present invention.

FIG. 30 to FIG. 33 are block diagrams showing the smoothening calibrator in accordance with the preferred embodiment of the present invention.

FIG. 34 is a block diagram showing a time mismatch calibrator in accordance with the preferred embodiment of the present invention.

FIG. 35 is a block diagram showing the input buffer in the time mismatch calibrator in accordance with the preferred embodiment of the present invention.

FIG. 36 is a block diagram showing the FIR filter in the time mismatch calibrator in accordance with the preferred embodiment of the present invention.

FIG. 37 is a block diagram showing the output buffer in the time mismatch calibrator in accordance with the preferred embodiment of the present invention.

FIG. 38 is a block diagram showing the unsigned to 2's complement converter in the time mismatch calibrator in accordance with the preferred embodiment of the present invention.

### DETAILED DESCRIPTION

Hereinafter, the preferred embodiments of the present invention are explained in details by referring to the attached figures. The same reference numbers described in the figures denote the same means and steps.

FIG. 1 is a block diagram showing a simplified configuration of M-channel TI-ADCs in accordance with a prior art. As shown in FIG. 1, the fundamental architecture of the M-channel TI-ADCs consists of an analog demultiplexer at input side, M parallel ADCs, and a digital multiplexer at output side.

Moreover, prior to explaining the present invention in details, the present invention referring to M-channel TI-ADCs model (hereinafter M is assumed to be 2 for explanation) is explained in details to analyze the cause and effect of mismatches (i.e., offset mismatch, gain mismatch, and time mismatch). If necessary, the model will be specified for the explanations. The two ADCs sample input analog signal at half of the sampling rate L. And analog demultiplexer selects the channel connected to the specific ADC in round robin manner to perform conversion of input signal.

Let u(t) be a bandlimited signal with bandwidth of ±f_{sig}. For mismatch errors analysis, the quantization effects and bandwidth mismatch are ignored. If the two channels are ideal, the output of sampled and multiplexed signal in the 2-channel TI-ADCs model can be expressed as equation (1).

$${z}_{1} ( t ) = u ( t ) {\sum }_{n} δ ( t - {nT}_{i} ) \\ {z}_{2} ( t ) = u ( t ) {\sum }_{n} δ ( t - {nT}_{i} - {T}_{i} / 2 ) \qquad ( 1 )$$

Wherein, Ti is referred as sampling period of each clock for the ADCs and Ti=1/fi. z1 and z2 are odd and even samples, respectively. fs denotes the sampling frequency in frequency domain. Moreover, the operation of ideal 2-channel TI-ADCs where no mismatches occur is expressed as equation (2).

$${Z}_{1} ( jω ) = \frac{1}{{T}_{i}} U ( jω ) * {\sum }_{n} δj ( ω - n {ω}_{i} ) \\ {Z}_{2} ( jω ) = \frac{1}{{T}_{i}} U ( jω ) * {\sum }_{n} δj ( ω - n {ω}_{i} ) {e}^{- jω {T}_{i}} \qquad ( 2 )$$

Wherein, ωi=2πfi and ranges from −π<ω<π. the resultant spectrum, in such case, suffers from heavy aliasing. Ideally, spectral copies around ±fi cancel each other when performing addition of Z1(jω)+Z2(jω). Multiplexing function is replaced by addition in discrete time signals resulting in original signal U(jω).

The analog input signal u(t) that is sampled by the front end sample and hold circuit of the channels for n samples sequence of u(n) can be expressed as the following equation (3).

u(n)=Δo+(1+Δg)z(nT_{g}−Δτ) (3)

According to the above equation (3), Offset mismatch is introduced because of different offsets in ADC channels resulting in dc value and periodic additive pattern in ADC output. In frequency domain, the periodic pattern appears as a tone at channel sampling rate fs/2.

Gain mismatch between TI-ADC channels results in amplitude modulation of input signal by the sequence of channel gains. The copies of input signal spectrum appear in around the center of sampling frequency fs/2 due to gain mismatch error.

Ideally, each channel should sample the input signal uniformly at fs/M, but due to time mismatch the output exhibits non-uniform sampling. Let Δτ denotes the small delay in the sampling, then the input u(t) will become to be expressed as equation (4).

$$u ( t + Δτ ) ≅ u ( t ) + Δτ \frac{d u}{d t} \qquad ( 4 )$$

Wherein, Δτ(du/dt) denotes the time mismatch error between two channels of TI-ADC. Let's imply this time mismatch error effect by considering 2-channel TI-ADCs, and consider the input u(t)=cos(ωt+φ), where ω=2πf and f is input frequency. To show the impact of Δτ, multiplexed output can be expressed as the following equation (5).

$$z ( n ) = cos \frac{ωΔτ}{2} cos [ ( ω nT , + \frac{ω Δ τ}{2} ) + φ ] + sin \frac{ω Δτ}{2} [ ( ω - \frac{{ω}_{s}}{2} ) {nT}_{s} + \frac{ωΔτ}{2} + φ ] \qquad ( 5 )$$

The second term in equation (5) represents the image of the first term, also known as alias component. The phase shift of (ωΔτ)/2 is added because of average delay of Δτ/2 that occurs due to sampling time error of Δτ in the second ADC. The immediate effect of time mismatch limits the SNR (Signal to Noise Ratio) of TI-ADC system to the SNR expressed as equation (6).

$$S N R = \frac{1}{{π}^{2} {Δτ}^{2} {f}^{2}} \qquad ( 6 )$$

As shown in equation (6), an effect of sample time mismatch degrades the performance of TI-ADC in terms of SNR. Let's consider the time mismatch in term of derivative that is used for error correction according to the mismatches. The additive time error in frequency domain becomes Δτ[jωU(jω)] by translating the additive time error Δτ(du/dt). Incorporating the translated additive time error into equation (2) results in equation (7).

$${Z}_{1} ( jω ) = \frac{1}{{T}_{i}} U ( jω ) * {\sum }_{n} δj ( ω - n {ω}_{i} ) \\ {Z}_{2} ( jω ) = \frac{1}{{T}_{i}} [ U ( jω ) + jωΔτ U ( j ω ) ] * {\sum }_{n} δ j ( ω - n {ω}_{i} ) {e}^{- jω {T}_{i}} \qquad ( 7 )$$

For Z₂(jω), when n=0 in the second term of equation (7), δ(ω)e_{-jωT}_{ᵢ}=δ(ω). Hence, Z₂ becomes equation (8).

$${Z}_{2} ( jω ) = \frac{1}{{T}_{i}} [ U ( jω ) + jωΔτ U ( jω ) ] \qquad ( 8 )$$

Equation (8) converges to the central point of the present invention. Where, Z₂ contains U(jω), and that is the input signal spectrum and first order shaped version of U(jω) (i.e., jωΔτU(jω)).

This analysis derives the main idea behind using derivative filter in the present invention for time skew error calibration.

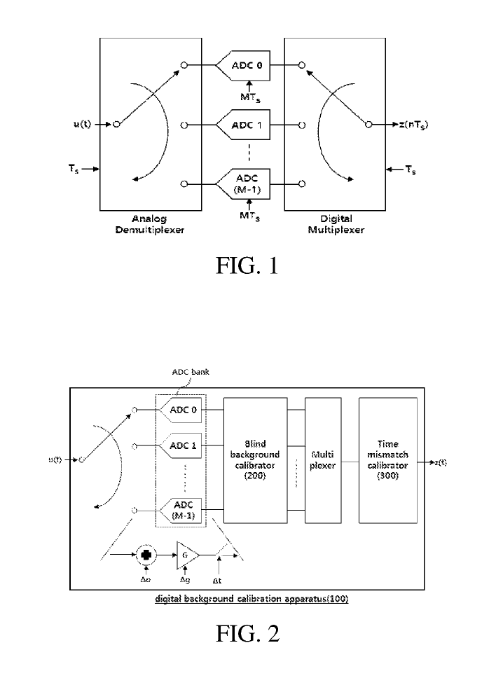

FIG. 2 is a block diagram showing a configuration of a digital background calibration apparatus for mismatch in M-channel TI-ADCs in accordance with the preferred embodiment of the present invention.

As shown in FIG. 2, the digital background calibration apparatus 100 for mismatch in M-channel TI-ADCs, comprises ADC banks including at least more than one ADC for converting input analog signal into digital samples by time interleaving the input analog signals and then sampling them to a plurality of ADC channels, a blind background calibrator 200 calibrating offset mismatch and gain mismatch for the converted digital samples, a multiplexer combining a plurality of samples calibrated through the blind background calibrator 200, and a time mismatch calibrator 300 calibrating time mismatch for the multiplexed digital samples.

The ADC bank comprises M numbers of equivalent ADCs, and the input analog signal is sampled with sampling rate of fₛ/M, and inputted to M numbers of ADCs. Wherein, fₛ denotes overall sampling rate.

The digital background calibration apparatus 100 for mismatch in M-channel TI-ADCs, calibrates the offset mismatch and gain mismatch based on the statistical characteristics of on statistical characteristics of the digital signal which is sampled and outputted in channel by channel, and the time skew mismatch is calculated using digital filter. The digital filter comprises a derivative filter and a fractional delay filter. The blind background calibrator 200 calibrates the offset mismatch and gain mismatch based on statistical characteristics of the digital signal which is sampled by ADC channel and outputted in channel by channel.

The multiplexer combines and outputs the digital samples calibrated in offset and gain mismatches in channel by channel through the blind background calibrator 200.

The time mismatch calibrator 300 measures the time error of the combined digital signal using the digital filter, and calibrates the time mismatch based on the estimated time error. The calibrations of the offset mismatch, the gain mismatch and the time mismatch are performed in consecutive order.

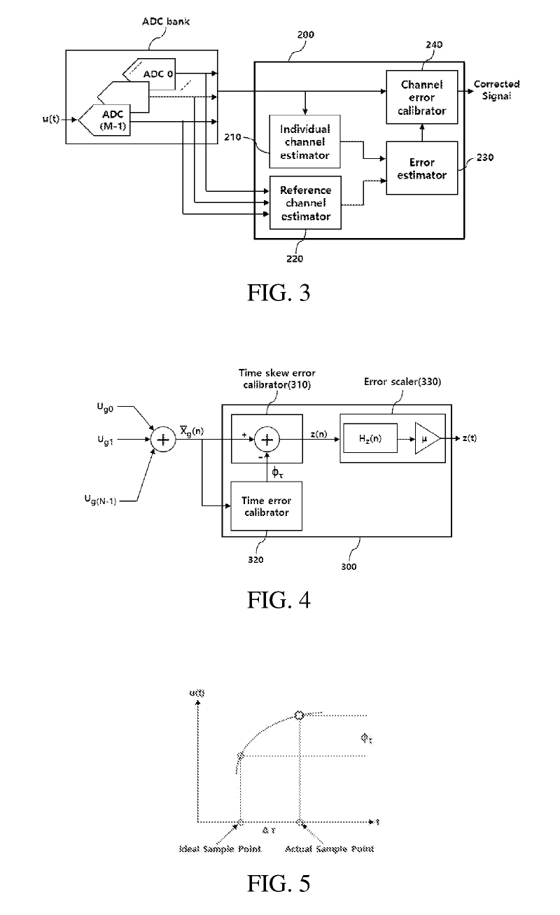

The calibrations for the offset mismatch and the gain mismatch are explained in details by referring to FIG. 3, and the calibration for the time mismatch is explained in details by referring to FIG. 4.

FIG. 3 is a block diagram showing a configuration of a blind background calibrator of the digital background calibration apparatus for mismatch in M-channel TI-ADCs in accordance with the preferred embodiment of the present invention. As shown in FIG. 3, the blind background calibrator 200 for calibrating the offset mismatch and gain mismatch comprises a reference channel estimator 220 for estimating reference channel, an individual channel estimator 210 for estimating each ADC channel, an error estimator 230 for estimating the offset error and the gain error based on the estimated reference channel and each ADC channel, and an channel error calibrator for calibrating mismatch based on the estimated error. In each component comprising the blind background calibrator 200, the offset mismatch and gain mismatch are calibrated by using similar mechanism, and the characteristics of each component is separately explained in details for the offset mismatch and gain mismatch, respectively. The present invention is based on statistical model of signal analysis where channel wise mean of input signals is used to estimate probable error.

Theoretically without any mismatches presented in the ADCs, the average over all n samples, x₀(n) in a given channel should be identical for all M channels. In the ideal case without existing offset errors, the mean value of the input signal which is zero should be equal. The error caused by the offset mismatch which can be occurred in each plurality of channels appears the periodic error in the final digital signal in which the digital samples sampled for each channel are combined by the multiplexer. In this regards, the offset mismatch calibration performed in the blind background calibrator 200 compares the output of each ADC channel with that of the reference channel by considering the output of the reference channel.

The reference channel estimator 220 estimates the offset of the reference channel, and the offset reference estimation is acquired by taking the mean value of all the samples from all channels according to the following equation (9).

$${x}_{o , ref} = \frac{1}{M * n} {\sum }_{i = 0}^{( N * n - 1 )} {u}_{i} \qquad ( 9 )$$

The individual channel estimator 210 estimates each channel offset by averaging the samples of each channel with its corresponding number of samples, and generates the channel estimation which is given in equation (10).

$${x}_{o , ch ( M )} = \frac{1}{n} {\sum }_{i = 0}^{( n - 1 )} {u}_{i} \qquad ( 10 )$$

In order to acquire more precise error estimation, the error estimator 230 estimates each channel offset error by calculating the difference between the estimated reference offset and average of each channel offset. The channel offset estimation is required to model the deviations of offset error in each channel that can occur in real systems.

The difference between the estimated reference offset with each channel offset average are the corresponding offset errors, Δo, for each channel, and the offset errors Δo need to be subtracted in channel wise from the actual TI-ADC output. The offset error is represented as shown in equation (11).

Δo_{M}=x_{o,ch(M)}−x_{o,ref} (11)

The channel error calibrator 240 calibrates the offset mismatch for each ADC channel by subtracting the ADC channel wise estimated offset error from the output samples of the corresponding ADC channel according to equation (12). So the offset corrected samples can be represented as (12).

x_{o,M}(n)=u_{M}(n)−Δo_{M} (12)

The gain mismatch coefficient identification is based on the consideration that all channels of ADCs produce the same power without any mismatch. Thus if the gain mismatch exists, the power of the channels is also caused inequality. Hence, the gain mismatch can be estimated by relating the average power of each channel to the average power of a reference channel of the offset corrected output of TI-ADC.

In the prior arts of K. Yang, S. Tian, P. Ye, P. Zhang and Y. Zheng, “A statistic-based calibration method for TI-ADC system,” Mathematical Problems in Engineering, Volume 2015, Hindawi Publishing Corporation, and C. Luo, L. Zhu, and J. H. McClellan, “Coordinated blind calibration for time-interleaved ADCs,” IEEE Int. Conf. Acoustics, Speech and Signals., pp. 3890-3894, May 2013, the gain error calibration is estimated and corrected with the same method applied in the present invention. In both the prior cases, the first channel is considered as the reference channel and the gain error is corrected for other channels except for the first channel. That is, the gain error of the first channel is ignored. It causes a disadvantage that the error correction cannot be accurately corrected.

The reference channel estimator 220 estimates the average power of the reference channel, and the average power of the reference channel is calculated by equation (13).

$${x}_{g , ref} = \frac{1}{M * n} {\sum }_{i = 0}^{( M * n - 1 )} {x}_{o , i}^{2} \qquad ( 13 )$$

The first channel error of the ADC channels is estimated using the reference channel, the first channel is considered as the reference channel, and then the first channel is used to estimate the gain errors of the other channels.

Furthermore, the gain channel error approximation method is following the concept used in the offset calibration. The squared values of the offset corrected M-channel samples are averaged across n values to extract the average power of a specific channel. The squared values can be expressed as equation (14).

$${x}_{g , ch ( M )} = \frac{1}{n} {\sum }_{i = 0}^{( n - 1 )} {x}_{o , i}^{2} \qquad ( 14 )$$

The error estimator 230 estimates gain errors based on the reference estimation and the channel estimated values. Since the gain errors are multiplied with input samples in TI-ADC, hence the cancellation process is based on estimation of gain errors, and then the calculated values are divided over the corresponding channel values.

As expressed in equation (15), while the gain error values (Δgch(N−1)) of the other channels are calculated adaptively with the first channel estimated value, the gain error value(Δgch(0)) of the first channel is calculated by using Xg,ref.

$$Δ {g}_{ch ( 0 )} = \frac{{x}_{g , ch ( 0 )}}{{x}_{g , ref}} \\ Δ {g}_{ch ( M - 1 )} = \frac{{x}_{g , ch ( M - 1 )}}{{x}_{g , ch ( 0 )}} \qquad ( 15 )$$

The channel error calibrator 240 finally performs the gain mismatch correction by dividing the channel error values Δg with the respective channel input values as shown in equation (16).

$${x}_{g , M} ( n ) = \frac{{x}_{o , M} ( n )}{Δ {g}_{M}} \qquad ( 16 )$$

Even the present invention explains the configuration for calibrating the offset mismatch and the gain mismatch by integrating them into a single configuration, the configuration for calibrating the offset mismatch and the gain mismatch can be separately implemented as well. The calibration for the offset mismatch is performed first, and then the calibration for the gain mismatch is then successively performed.

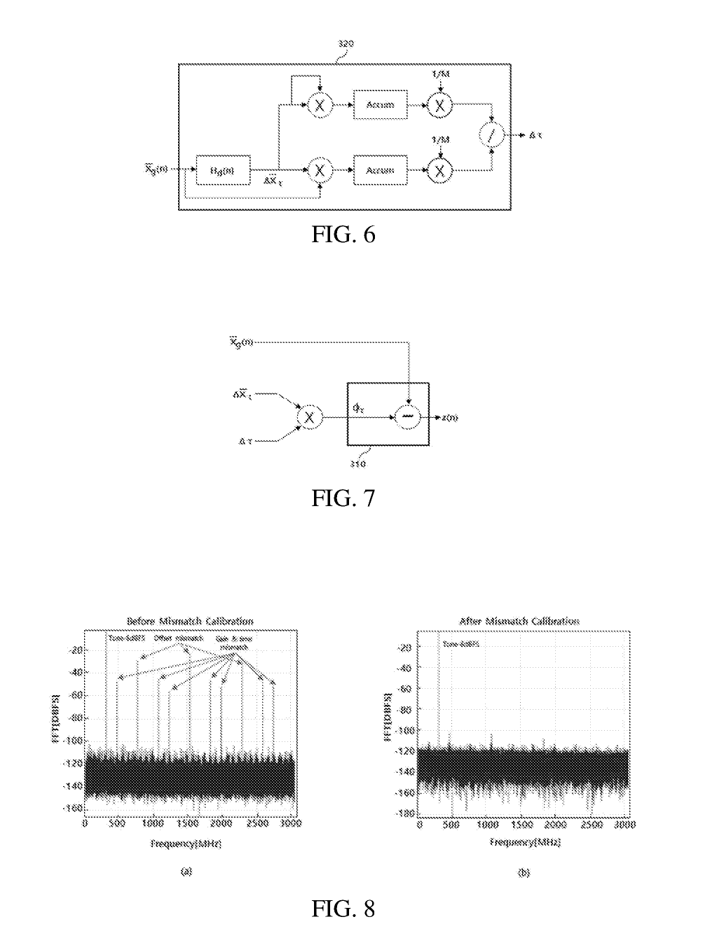

First of all, the time skew error estimation and correction in accordance with a preferred embodiment of the present invention are explained in details by referring to FIG. 4, FIG. 5, and FIG. 6.

FIG. 4 is a block diagram showing a configuration of a time mismatch calibrator of the digital background calibration apparatus in M-channel TI-ADCs in accordance with the preferred embodiment of the present invention. FIG. 5 shows a sampling error caused by timing skew in accordance with the preferred embodiment of the present invention. And FIG. 6 is a block diagram showing a configuration of a time error calibrator of the time mismatch calibrator in accordance with the preferred embodiment of the present invention. In addition, FIG. 7 is a block diagram showing a configuration of a time skew error calibrator of the time mismatch calibrator in accordance with the preferred embodiment of the present invention.

As shown in FIG. 4, the time mismatch calibrator 300 for correcting time mismatch performs the time mismatch calibration by taking the digital samples as inputs that are recombined through the multiplexer after the offset mismatch and the gain mismatch of each ADC channel sample are corrected through the blind background calibrator 200. Before the time skew calibration for the digital samples, the offset error and gain error must be firstly calibrated. Since the extra high frequency tones cause problems that degrade overall performance of TI-ADCs, the extra high frequency tones that might be occurred in the course of performing the gain mismatch error correction in the blind background calibrator 200 are preferred to be removed. The cancelling of the extra high frequency tones occurred in the offset and gain mismatch calibrated digital samples can be performed by subtracting smoothening coefficient (i.e., the value subtracting the average of all the samples for each channel from the average of all of the digital samples for all M-channel) from the gain mismatch corrected digital samples through the blind background calibrator 200.

Moreover, the cancelling of the extra high frequency tones can be sequentially performed in the blind background calibrator 200 performing the gain mismatch calibration, and means for cancelling the extra high frequency tones can be separately configured (not shown).

In addition, X̅_{g} shown in FIG. 4 is the digital sample recombined by the multiplexer after the gain calibration. The time mismatch calibrator 300 comprises the time skew error calibrator 310 estimating the time skew error from the recombined digital samples X̅_{g}, the time skew error calibrator correcting the timing skew error from the digital samples X̅_{g} based on the estimated error, and the error scaler 330.

An estimation of the multiplexed input digital samples and the first derivative of the corresponding multiplexed input digital samples is required to calculate the time error parameters. Each gain mismatch corrected and multiplexed digital sample can be considered as a sum of an ideal signal x_{ideal} and an error term φτ as shown in FIG. 5.

As shown in FIG. 6, the time error calibrator 320 uses the derivative filter Hd(n) for the error estimation. The derivative filter Hd(n) does not require any coefficient assumption and LUT (look-up-table) because the filter used has a constant coefficient as compared with traditional techniques. Thus it has the effect of reducing hardware complexity and hardware resource consumption. In addition, for time error correction, the major processor of the time error calibrator is the differentiator FIR filter, and for scaling the digital samples, fixed fractional delay filter is used. The derivative of the input signal can be approximated as shown in equation (17)

ΔX̅ᵣ=X̅_{g} [symbol] H_{d}(n) (17)

The Hd(n) represents impulse response of the differentiator filter which is convoluted with the gain corrected samples X̅_{g}. The differentiator filter can be implemented by exploiting the inverse discrete time Fourier transform of Hd(e^{jω}) to for ωε(−π, π). The differentiator filter can be represented in the form of equation (18).

$${H}_{4} ( n ) = \{ \begin{matrix}\frac{{( - 1 )}^{*}}{n} , n \neq 0 \\ 0 , n = 0\end{matrix} \qquad ( 18 )$$

If no time skew error presents at the ideal signal x_{ideal} shown in FIG. 5, the average of the ideal samples and the derivative is zero as the ideal samples are orthogonal to the derivative corresponding to the ideal samples by equation (19). So for a small timing skew Δτ, the delayed signal is X̅_{g}. The average of the signal, X̅_{g} extracts the skew part from the samples, and the term is symmetrical to the time skew error and multiplication of the square of derivative and the timing skew error Δτ as shown in following equation (20).

$$\overline{{x}_{ideal} \times \frac{d {x}_{ideal}}{d t}} = 0 \qquad ( 19 )$$

From equation (20), the small time skew Δτ can be calculated. So the estimated error part can be extracted by the multiplication of small timing skew Δτ and derivative ΔX̅_{τ}, which is the calculation according to equation (21).

X̅_̅{̅g̅}̅×̅Δ̅X̅_̅{̅τ̅}̅=Δτ×(̅Δ̅X̅_̅{̅τ̅}̅)̅²̅ (20)

φg=Δτ×ΔX̅ₜ (21)

That is, the time error calibrator 320 calculates impulse reaction using the differentiate filter to the multiplexing digital sample, convolutes the impulse reaction with the multiplexing digital sample, calculates time skew by dividing average value of square of the convolution result to average value of multiply of the convolution result and the multiplexing digital sample. The time error calibrator 320 calculates time error by multiplying the calculated time error and the convolution result. As shown in FIG. 7, time skew error calibrator 310 calibrates the time skew error by cutting the calculated time error from the multiplexing digital sample, using equation (22).

z(n)=X̅_{g}−φ_{g} (22)

The ideal differentiator cannot be implemented and uses realizable filters for calculating approximations which are approximated to the ideal differentiator. The approximations can introduce phase and amplitude errors in the output which is limited by the Nyquist band. For this the error scaler 330, removes the phase and amplitude errors using the multiplexing digital sample that the time mismatch is calibrated and a fixed fractional delay filter with a scaling factor. An FIR approximation for the correction of the multiplexing digital sample, can introduce phase and amplitude errors to the samples. So a fractional delay filter follows a scaling constant μ, and the output is represented by equation (23) and (24).

Z̅(̅n̅)̅=z(n) [symbol] H_{z}(n) (23)

Z(n)=z(n) [symbol] z^{-D} (24)

The D in equation (24) is a positive real number that can be split into the integer part and fraction part. Also the D performs the desired band limited delay operation at the used sampling rate.

D=int(D)+d (25)

The integer part of the equation (25) is zero so it is concluded to D=d for the fractional delay filter, the amplitude scaling removes the performed amplitude error and phase error by multiplying output of the fractional delay filter and fixed constant scaling factor μ.

FIG. 8 is an exemplary view showing as a graph of output spectrum of 8-channel TI-ADCs in accordance with the preferred embodiment of the present invention.

To verify the calibration procedure of offset mismatch, gain mismatch and time mismatch of the present invention, extensive simulation is performed on 8-channel 12-bit TI-ADCs. In MATLAB, environment of the TI-ADCs is created and simulated with all the nonlinear errors. All the channels are modeled with an input sample and hold module, and the offset, gain and time errors are introduced separately to each channel Different errors are introduced separately for different channels, and 21-tap fixed FIR differentiator filter is used in the simulation. The scaling constant μ is 1.02 and it is chosen by iterative simulations to compensate the input-output amplitude error difference. FIG. 8 is an exemplary view showing an output spectrum of 8-channel TI-ADCs when the input frequency is f=0.1 fₛ. As shown in FIG. 8, in sampling frequency of 3.072 GHz, 1,000,000 samples are considered for simulation and each channel processes 125,000 samples.

FIG. 8(a) represents harmonic spectrum of offset, gain and time error which is un-calibrated to the wide range of error. FIG. 8(b) represents the spectrum after the digital calibration process completed. As shown in FIG. 8(b), the harmonics which are generated because of the offset, gain and time error are suppressed after the implement of the digital calibration is executed.

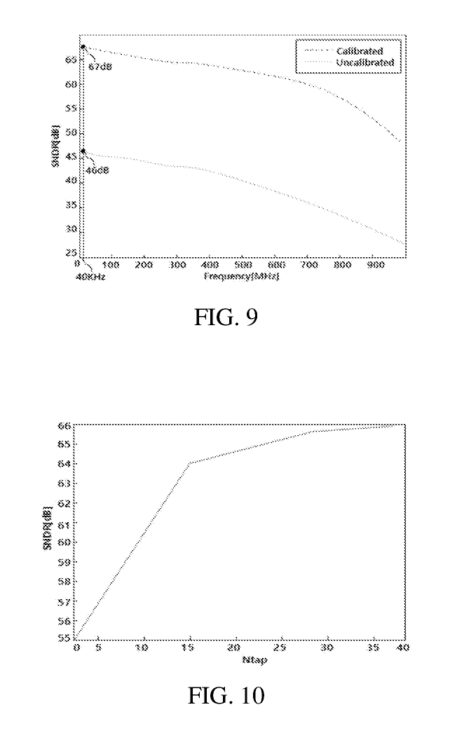

FIG. 9 is an exemplary view showing a change of SNDR of a correction before and after the correction of wideband signal in accordance with the preferred embodiment of the present invention.

The performance of the calibration process is assessed on a wideband signal. The input frequency of the TI-ADC is varied from 40 KHz to 1 GHz and the performance is observed by being limited to Nyquist band. As shown in FIG. 9, the SNDR of the both the uncalibrated signal and calibrated signal is decreased with the increasing of input signal frequency. Maximum 67 dB SNDR is achieved when the input frequency is 40 KHz and the un-calibrated SNDR is 46 dB on that particular point. An improvement of 21 dB is noticed because of the proposed calibration method of the present invention. The signal is more vulnerable to noise in high frequencies, but a minimum signal 49 dB SNDR of calibrated by the calibration method of the present invention is achieved at 1 GHz. The maximum achieved ENOB and SFDR of the calibrated signal in the present invention are 10.83 and 76.8 dB respectively.

FIG. 10 is an exemplary view showing as a graph of a change of SNDR value according to the number of filter tabs in accordance with the preferred embodiment of the present invention.

As discussed earlier, the only one differentiator filter is used for time skew calibration in mismatch calibration method of the present invention. As shown in FIG. 10, the time skew calibration performance is improved rapidly with the change of filter tapping. For 4-tap differentiator filter, the calibrated SNDR is 55 dB, which means a very low performance of the TI-ADCs. However, for 30-tap differentiator filter, the calibrated SNDR is 65.6 dB, which means a drastic improve of the TI-ADC performance.

FIG. 11 is a flow diagram showing a procedure of the digital background calibration method for mismatch in M-channel TI-ADCs in accordance with the preferred embodiment of the present invention.

As shown in FIG. 11, the input analog signal to the apparatus of digital background calibration for mismatch in M-channel TI-ADCs is converted into digital samples by time interleaving for a plurality of ADC channels (S110).

The offset error of the digital samples for the converted plurality of ADC channels is estimated and calibrated through the blind background calibrator 200 (S120). The offset error for the digital samples is estimated for each ADC channel by estimating the offset of the reference channel with calculating average value of the digital samples outputted from the plurality of channels through the blind background calibrator 200, by estimating the offset for each channel with calculating average value in each channel for the digital samples outputted from the plurality of channels, and by calculating the difference between the offset of the estimated reference channel and the offset of the estimated offset for each channel. The calibration for the offset mismatch of the digital samples is performed for each ADC channel by subtracting the offset error calculated for each ADC channel from the digital samples outputted from each ADC channel through the blind background calibrator 200.

The gain error of the digital samples for each plurality of channels in which the offset mismatch is calibrated is estimated and calibrated through the blind background calibrator 200 (S130). The gain error for each ADC channel is estimated through the blind background calibrator 200 by estimating average power of the reference channel with square average of the offset error calibrated digital samples for each plurality of ADC channels, by calculating the gain error of the first channel with dividing the first channel average power for the plurality of ADC channels by the estimated reference channel average power wherein the average power for each channel is calculated with averaging the offset calibrated samples for each channel, and by calculating the gain error for the other channels with the same method as that for the first channel wherein the first channel becomes the reference channel.

The gain mismatch of the digital samples for each ADC channel is calibrated through the blind background calibrator 200 by dividing the digital samples for each ADC channel by the calculated gain error for each ADC channel. Moreover, the digital samples for each ADC channel have been calculated according to the calibrating process of the offset mismatch. And extra high frequency tone is generated in the process of the gain mismatch calibration, and the process of cancelling the extra high frequency tone has been processed and the extra high frequency tone has been removed. The extra high frequency tone can be canceled by the blind background calibrator 200 or canceled by a special dedicated component (not shown). The offset error and gain error calibrated digital samples for each ADC channel through the blind background calibrator 200 are outputted to the multiplexer (S140).

The timing error of the multiplexed digital samples are estimated and calibrated through the time mismatch calibrator 300 (S150). The timing error is estimated through the time mismatch calibrator 300 by calibrating inpulse response using the multiplexed samples and the differential filter, by calculating the timing skew with dividing the average value of the value multiplying the result convolving the impulse response and the multiplexed digital samples with the multiplexed digital samples by the average value for the squared value of the convolved result, and by multiplying the calculated timing skew with the convolved result. The timing error calibration for the corresponding digital sample is performed through the time mismatch calibrator 300 by subtracting the calculated timing error from the multiplexed digital sample.

The phase and amplitude errors of the digital samples which can occur in the course of performing the timing error calibration are canceled and calibrated through the error scaler 330 (S160). In calibrating the phase and amplitude error as described above, the error scaler 330 with a fractional delay filter and scaling factor calibrates the phase error and amplitude error of the digital samples by removing the phase and amplitude errors of the digital samples in which offset error, gain error and timing error are calibrated.

Hereinafter the implementation issues of TI-ADC are discussed in details by referring to the accompanying drawings.

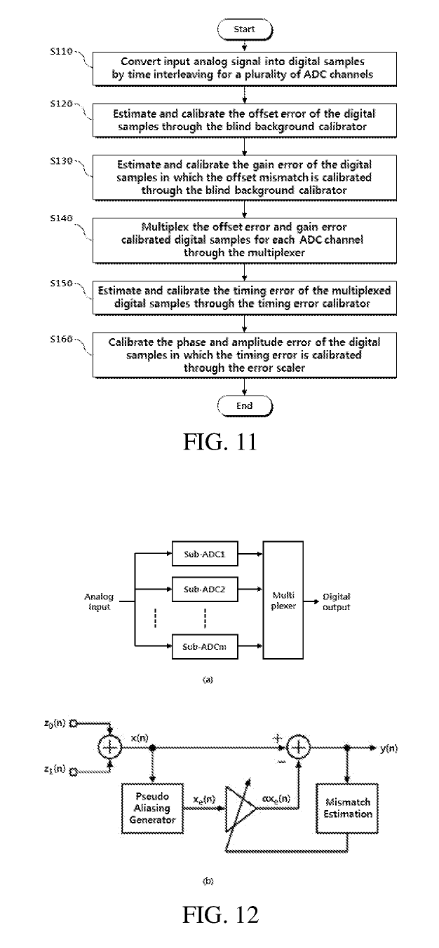

FIG. 12 is an exemplary view briefly showing a fundamental structure of TI-ADCs and an apparatus for calibrating mismatch in accordance with the preferred embodiment of the prior art.

In a system for processing data at high speed, high speed ADC for converting analog signal to digital signal is essentially required. While signal conversion is performed using a single ADC in the past, high speed ADC technology which can perform the conversion at high speeds becomes to be required for fast processing massive amounts of data, as the recent society approaches to information communication based society. To solve the above problem, TI-ADC applying time interleaving structure connecting plurality of same sub-ADCs in parallel is being developed and utilized.

As shown in FIG. 12(a), a basic structure of TI-ADC comprises a plurality of sub-ADCs and a multiplexer. Wherein the sub-ADCs are used for sampling the input analog signals and converting them into the digital samples, and the multiplexer can be used for multiplexing the converted channel based digital samples and combining them into a single signal. The TI-ADC has advantage of being capable of implementing high resolution and high speed ADC by applying time-interleaving structure, operating different phase sampling clock in parallel and sampling the analog signal based on each channel. However, in the sampling process with the clock, unavoidable mismatches (offset mismatch, gain mismatch and time mismatch) among sub-ADCs are occurred. These mismatches involve problems which drastically degrade performance of overall sub-ADCs comprising TI-ADC.

The mismatch which occurs in TI-ADC causes distorted output signal by the sum of aliased version of input signal and spurious tone, and considerably decreases SNDR (Signal to Noise and Distortion Ratio) and SFDR (Spurious Free Dynamic Range) of TI-ADC. For calibrating the mismatch, many calibration apparatuses have been developed and used. Among them, one example of the existing calibration methods which are relatively recently known is shown in FIG. 12(b).

FIG. 12(b) is an exemplary view briefly explaining an existing calibration apparatus which calibrates the mismatch using pseudo aliasing signal. As shown in FIG. 12(b), in case of 2-channel TI-ADC, an existing calibration apparatus using pseudo aliasing signal calibrates the mismatchs by applying the pseudo aliasing signal rather applying adaptive filter bank which is generally used. The existing calibration apparatus generates the psuedo aliasing signal and calibrates the mismatches by adding or subtracting the psuedo aliasing signal to/from the aliasing signal occurred in TI-ADC.

While the apparatus using the psuedo aliasing signal uses only one differentiator filter, it has disadvantage of using a feedback signal and a notch filter, which increase complexity for estimating the gain and time mismatches. Thus, the present invention provides a digital background calibration apparatus which can perform digital processing at high speed by calibrating the mismatches through simple addition, subtraction and shift arithmetic operations. Moreover, the present invention provides a digital background calibration apparatus which reduces hardware complexity and increases hardware resource efficiency by calibrating the offset mismatch and gain mismatch by using the statistical characteristics of the digital signal and calibrating the time mismatch by using FIR filter.

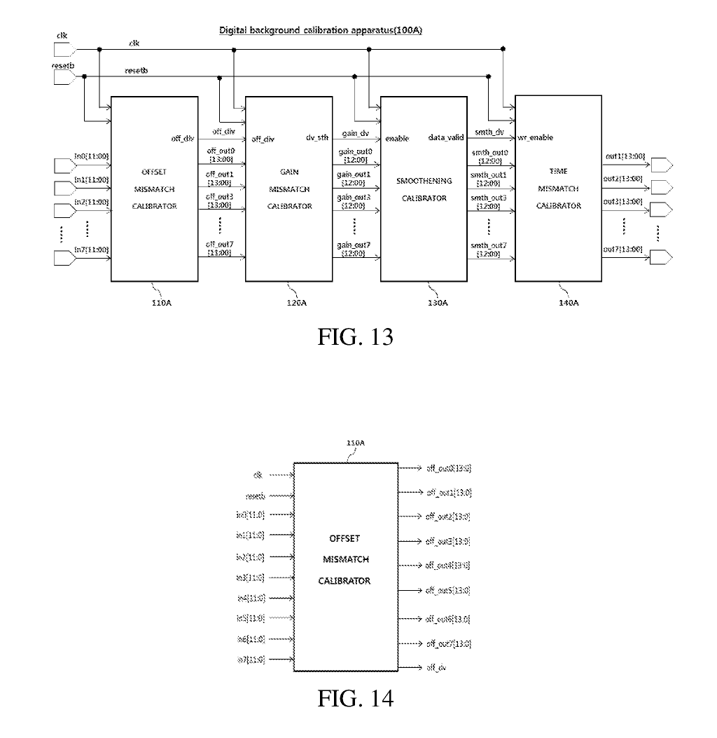

FIG. 13 is a block diagram showing a digital background calibration apparatus for mismatches in M-channel TI-ADCs in accordance with the preferred embodiment of the present invention Hereinafter the present invention is explained in details by assuming the M-channel TI-ADC as 8-channel TI-ADC. However, the present invention is not limited in 8-channel, it can surely be applied to any number of channels as well.

As shown in FIG. 13, the digital background calibration apparatus comprises an offset mismatch calibrator 110A configured to calibrate offset mismatch for each channel with receiving the digital samples from TI-ADC, a gain mismatch calibrator 120A configured to calibrate gain mismatch for the offset calibrated digital samples which are received from the offset mismatch calibrator 110A, a smoothening calibrator 130A configured to remove extra high frequency tone occurred in the course of calibrating the gain mismatch, and a time mismatch calibrator 140A configured to calibrate time mismatch for the offset and gain calibrated digital samples. Each processing unit for offset mismatch calibration, gain mismatch calibration, smoothening and time mismatch calibration comprises adders, subtractors, multipliers, dividers or the combinations thereof and their controller. Adders, subtractors, multipliers, dividers and controller are the key computational units. Each processing unit comprises at least a single buffer memory. The buffer memory is the key unit for high speed digital processing. The buffer memory takes an important role to minimize resources for designing the digital background calibration apparatus 100A. That is, total four buffer memories contained in each of the units are used to keep very small minimum memory resource as compared with the existing other hardwear implementations.

The 8-channel TI-ADC converts the inputted analog signal to digital samples by sampling the inputted analog signal with 8 channels. The converted digital samples are provided to the offset mismatch calibrator 110A along with 2.5 ns clock signal and reset signal. The digital background calibration apparatus 100A synchronizes calibrations of mismatches for the digital samples of each channel by using a synchronization signal. The synchronization signal is generated in the previous calibrator of a specific calibrator. The digital background calibration apparatus 100A is a real-time system which keeps performing the calibrations until the input of the digital samples is reset or switched off, and thus the design is performed without incorporating any synchronization signal as input. The mismatch calibrations are performed in 3 mismatches in the order of offset mismatch, gain mismatch and time mismatch.

In the offset mismatch calibrator 110A and the gain mismatch calibrator 120A, the calibrations are performed based on the statistical characteristics of the target signals, especially based on the sum and average of the target signals. In the offset mismatch calibrator 110A and the gain mismatch calibrator 120A, the calibrations are performed by calculating the mean value and mean square value for the digital samples inputted per channel respectively. The offset mismatch calibrator 110A is configured to calibrate the offset mismatch of the digital samples per each channel by subtracting the estimated offset mismatch from the output per each channel.

The gain mismatch calibrator 120A is configured to calibrate the gain mismatch of the digital samples for each channel, wherein the gain mismatch is calibrated for the offset mismatch calibrated digital samples based on the calculated root mean square value and particular constant value.

The smoothening calibrator 130A removes spike (extra high frequency tone) which occurs as a result of calibrating the gain mismatch. The removal of the spike is performed by the same mechanism as that being performed in the offset mismatch calibrator 110A.

The time mismatch calibrator 140A is configured to calibrate the time mismatch of the digital samples for each channel Wherein the digital samples are calibrated for the offset mismatch and the gain mismatch, and the time calibration is performed by using FIR filter.

The processes to calibrate the mismatches are pure digitally performed, and they are independent of the manufacturing process of TI-ADC for the digital background calibration apparatus, and have advantageous effects of reducing hardwear complexity and increasing efficiency of hardware resource.

FIG. 14 is a black diagram showing an offset mismatch calibrator in accordance with the preferred embodiment of the present invention.

As shown in FIG. 14, the offset mismatch calibrator 110A is the first block of the digital background calibration apparatus 110 and takes 12-bit digital samples per channel as the inputs (in0 to in7) from the 8-channel TI-ADC. The offset mismatch calibrator 110A incorporates clock and reset signal which are common for other calibrators excepting for some combinational logic blocks. The offset mismatch calibrator 110A generates and produces 14-bit off_dv signal (valid data offset signal). The off_dv signal is used for synchronization between the offset mismatch calibrator 110A and the gain mismatch calibrator 120A.

The offset mismatch calibrator 110A is configured to comprise an offset buffer 111A storing digital samples for each channel, a reference channel offset estimator 112A and an individual channel offset estimator 113A. The reference channel offset estimator 112A estimates the reference channel offset by calculating average value of all digital samples inputted per channel. And the individual channel offset estimator 113A estimates the offset for each channel by calculating average value of the digital samples inputted per each channel. The offset mismatch calibrator 110A is configured to estimate the offset mismatch for each channel by calculating difference value between the estimated offset for each channel and the offset of the reference channel, and to calibrate the offset of the digital damples for each channel by subtracting the estimated offset mismatch for each channel from the digital samples for each channel.

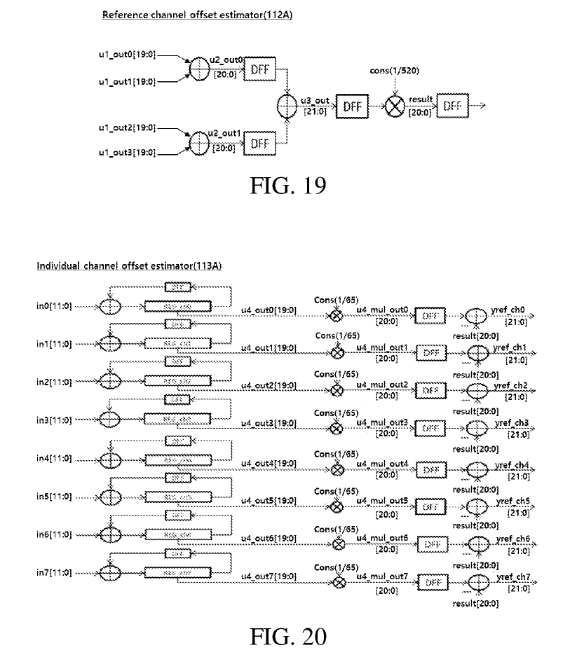

The reference channel offset estimator 112A and the individual channel offset estimator 113A are explained in details by referring to FIG. 18, FIG. 19 and FIG. 20.

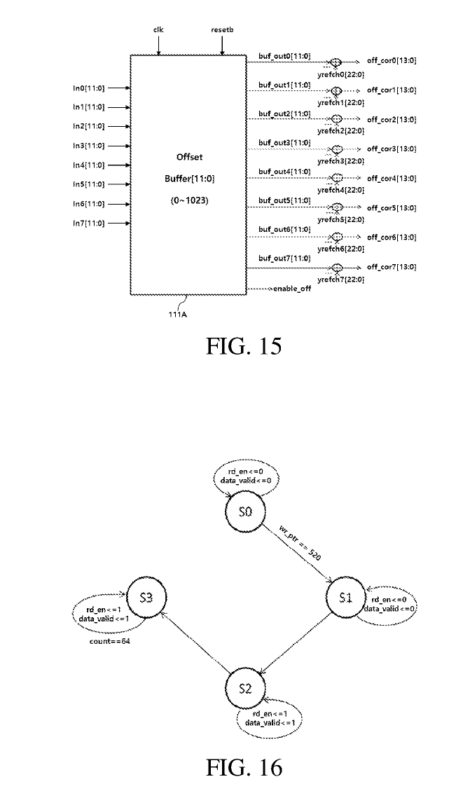

The offset mismatch calibrator 110A is pipelined for increasing data transmission rate and a plurality of DFFs (D-Flip Flop) are inserted in each pipeline for meeting timing requirements. FIG. 15 is a black diagram showing an offset buffer 111A in accordance with the preferred embodiment of the present invention. Since the real-time system needs to produce specific output signal continuously in high data transmission rate applications, all the samples cannot be taken as input altogether. For this reason, the offset mismatch calibrator 110A is configured to take total 512 samples as input to perform calibration of the offset mismatch. That is, the offset mismatch calibrator 110A is configured to take the inputs of first 512 samples from the 8-channel TI-ADC and store those in the offset buffer 111A (i.e., 64 samples per channel which are 512 samples). Even the digital background calibration apparatus 100A is explained to set 8-channel TI-ADC and total 512 samples as a preferred embodiment of the present invention, the total number of channels and samples can be chosen to different numbers according to the design of the digital background calibration apparatus 100A and TI-ADC.

As shown in FIG. 15, the offset buffer receives 64 digital samples per a channel and stores 512 samples. Since all the samples are stored in the offset buffer 111A, the calibration operation for the offset mismatch is performed after taking all the samples. Also next samples inputted in order are continuously stored in the offset buffer 111A. When the other 512 samples are stored, the next processing is performed. Except for the cases that the digital background calibration apparatus 100A is reset or switched off, the output from the offset buffer 111A is not stopped and outputted at every clock cycle.

The depth of the offset buffer 111A is 1024 samples and the width of the samples is 12-bit. The offset buffer 111A receives the digital samples directly from 8-channel TI-ADC, and stores the digital samples. In the final step for calibrating the offset mismatch, the offset buffer 111A is required to output samples for correction. It is due that many operations including reference channel calculation for the offset calibration are performed based on the digital samples directly inputted from the TI-ADC. The offset buffer 111A can be divided into two sections. The first section stores the digital samples in the offset buffer 111A or stores the logic for outputting the digital samples from the offset buffer 111A. Another section stores the logic for controlling the restoration or the output. The offset buffer 111A performs sorting the memory address in ascending order, and stores digital samples receiving from the TI-ADC after reset signal (resetb) becomes high state (in other words, reset is active low). Two pointers are used for read and write operations from/to the offset buffer 111A, and the operations are controlled by some control logics based on counter and state machine. When the reset signal is high state, the input is performed and the write operation is performed immediately for storing the input in the offset buffer 111A.

The state machine is as read pointer which keeps track of read operation, and its final counter reaches to 520. The state machine performs the operation after giving delays of two states (S1 and S2 as shown in FIG. 16) required for synchronization. Since the samples outputted per a channel in TI-ADC are inputted to the offset mismatch calibrator 110A per a clock cycle and stored in the offset buffer 111A, the read operation is always held. So the final state of the state machine will hold until the digital background calibration apparatus 100A is reset or switched off. When the offset mismatch calibrator 110A calibrates the offset mismatch and generates the first output, the offset buffer 111A outputs off_dv signal (valid data signal) for synchronization with the gain mismatch calibrator 120A because output of the offset buffer 111A is used in the final process for the offset calibration. The off_dv is synchronization signal and keeps high from first output of the offset mismatch calibrator 110A until the digital background calibration apparatus 100A keeps functional.

FIG. 16 is an exemplary view showing a state machine of the control logic for an offset mismatch calibrator in accordance with the preferred embodiment of the present invention.

As shown in FIG. 16, the state machine generates rd_en signal when the reset signal is high state. The rd_en signal is held as high until wr_ptr reaches to specific value. After the rd_en signal becomes high, the processing for read values from the offset buffer 111A is started. The rd_en signal makes performing re_ptr operation, and the counter value of the re_ptr is increased by 8 per each clock, because it is needed for reading 8 values from the offset buffer 111A per each clock. Once the first output starts to be outputted from the offset mismatch calibrator 110A, the read and write operations are performed continuously and simultaneously for storing new digital samples or outputting already established digital samples.

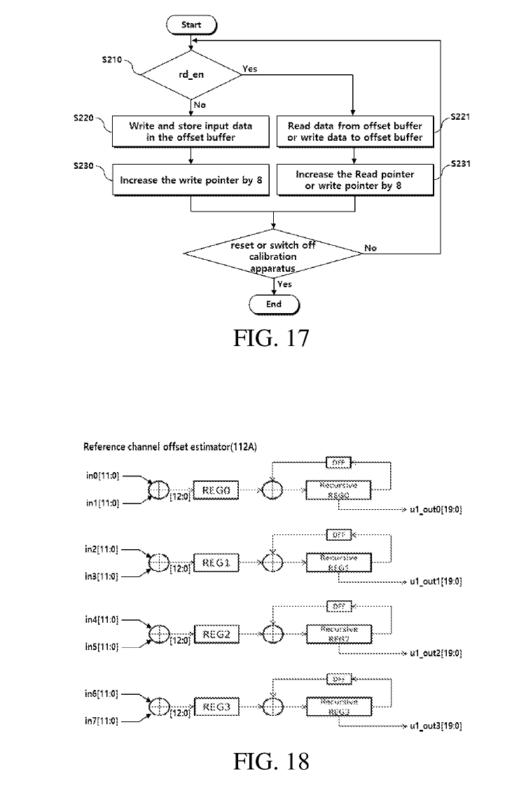

FIG. 17 is a flow diagram showing procedures performing read and write operations according to the logic of offset buffer in accordance with the preferred embodiment of the present invention.

The procedure performing read and write operation in accordance with the logic of the offset buffer 111A as shown in FIG. 17, reads the digital samples stored per each channel from the offset buffer 111A in the case that the state machine generates rd_en signal, or stores the digital samples through writing the digital samples inputted per each channel in the offset buffer 111A (S221). In other words, when the offset mismatch calibrator 110A performs offset calibration, the read and write operation are performed simultaneously. In the case of performing the read and write operations, counter values of read or write pointer are increased by 8 (S231). If the state machine does not generate rd_en signal (S210), after writing and storing the digital samples per channel inputted from the TI-ADC in the offset buffer (S220), the counter value of write pointer is increased by 8 (S230). Next, the read and write operations are performed repeatedly and continuously until the digital background calibration apparatus 100A of the present invention is reset or switched off.

FIG. 18 and FIG. 19 are block diagrams showing a reference channel offset estimator measuring the offset of reference channel in the offset mismatch calibrator in accordance with the preferred embodiment of the present invention.

As shown in FIG. 18 and FIG. 19, the reference channel offset estimator 112A receives and directly processes the digital sample outputted from the offset buffer 111A per channel.

The reference channel offset estimator 112A estimates and outputs offset of basic reference channel by calculating average after adding all samples (512 samples) which are inputted for offset mismatch per each channel. The reference channel offset estimator 112A generates 4 outputs by adding the inputted digital samples for each channel by 2 channels through 4 adders. Recursive registers (recursive REG1 to recursive REG4) are used for repetitive addition procedure for 64 samples per each channel Each of the recursive register outputs the results (u1_out0 to u1_out3) adding 2 channels. The reference channel offset estimator 112A adds 4 outputs (u1_out0 and u1_out1, u1_out2 and u1_out3) through 2 adders for 2 outputs, and generates 2 outputs (u2_out0, u2_out1). The bit length of the output is 21-bit. By adding the generated 2 outputs using a single adder, an output (u3_out) is generated and the bit length of the output is 22 bit.

The adder is pipelined per each channel for high speed calculation. DFF as shown in FIG. 18 and FIG. 19 is a unit which is necessary for managing the input and output critical path of each adder. The output, u3_out is the total sum of the digital samples for all channels. The offset of reference channel is measured by calculating average value of the total sum. For calculating the average value, division operation is needed but the division operation is very complex and has a problem that increases hardwear complexity.

In the present invention, the average value for the added total sum of all channels can be calculated through a multiplication operation by storing specific constant value in the offset buffer 111A in advance in accordance with the amount of samples which are gathered. It is effective for avoiding complex division operation and being capable of high speed operation. Meanwhile, the specific constant value for 8-channel 512-sample is set as 1/520 for explaining the present invention. The 1/520 is calculated and stored as a fixed point of (N, Q) form. The N shows the total number of bit for the constant and the Q shows the number of bit for fractional part. The reference channel offset estimator 112A calculates and outputs the reference channel offset by multiplying the constant value to the total sum (u3_out) of all channels calculated through a single multiplier. The reference channel offset is outputted as a fixed point format having the length of (21, 8).

FIG. 20 is a block diagram showing a reference channel offset estimator estimating the offset of the individual channel in the offset mismatch calibrator in accordance with the preferred embodiment of the present invention.

As shown in FIG. 20, the individual channel offset estimator 113A estimates the offset of each channel by estimating the average value of the total sum after calculating the total sum of the digital samples per each channel in order to calibrating the offset mismatch for each channel by estimating the offset for each channel. The sum of the digital sample per a channel means that 64-sample per each channel are added per each channel respectively, and the recursive register is used for calculating the total sum (64 samples) for each channel. Moreover, for generating the outcome of total sum of 64 samples per each channel, counter is provided from TI-ADC. The sum is 21-bit, and the total sum (u4_out0 to ou4_out7) per each channel is provided to the input of the multiplier. For calculating average value of the sum for each channel, the offset value (u4_mu1_out0 to u4_mu1_out7) for each channel is outputted by multiplying prestored constant value (1/65). The output is outputted as (21, 8) fixed point format. The offset mismatch calibrator 110A calibrates the offset of the digital samples for each channel by calculating the offset mismatch for each channel with calculating the difference value between the calculated reference channel offset value and the offset value for each channel, and by subtracting the calculated offset mismatch for each channel from the digital samples for each channel.

FIG. 21 is a block diagram showing a gain mismatch calibrator in accordance with the preferred embodiment of the present invention.

As shown in FIG. 21, the gain mismatch calibrator 120A receives the digital samples of which the offset mismatch for each channel is calibrated through the offset mismatch calibrator 110A. A synchronization signal called off_dv which is generated from the offset mismatch calibrator 110A is used for synchronizing the operations performed in the gain mismatch calibrator 120A, and especially used for storing offset calibrated digital samples into the gain buffer. The gain mismatch calibrator 120A is pipelined for satisfying data throughput and timing requirements. The gain mismatch calibrator 120A comprises a square calculator 121A which squares the digital samples for each channel in order to calibrate the gain mismatch, an individual channel average value estimator 122A calculating average value for each channel by summing the squared digital samples for each channel, a reference channel average value estimator 123A calculating average value after summing all of the squared digital samples, and a divider 124A.

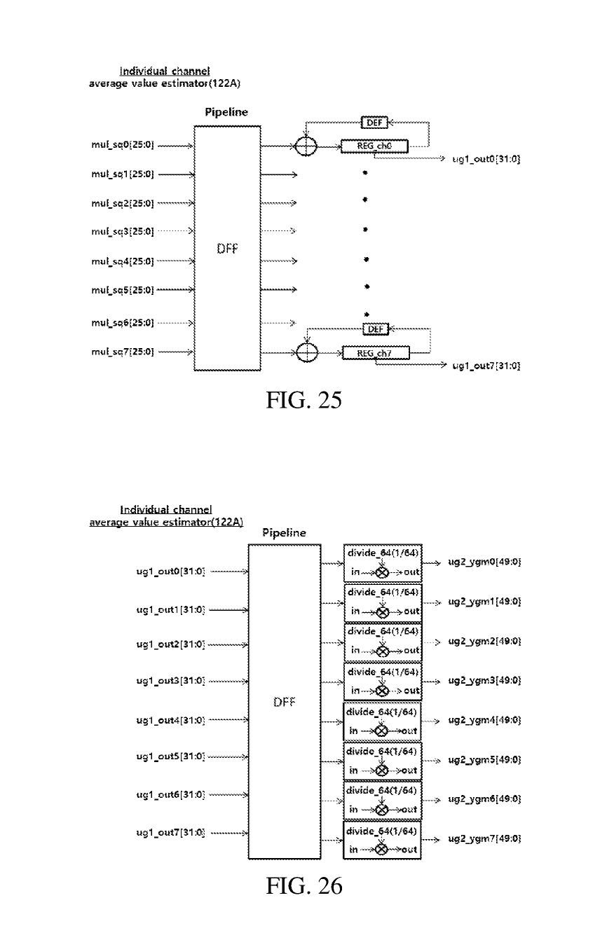

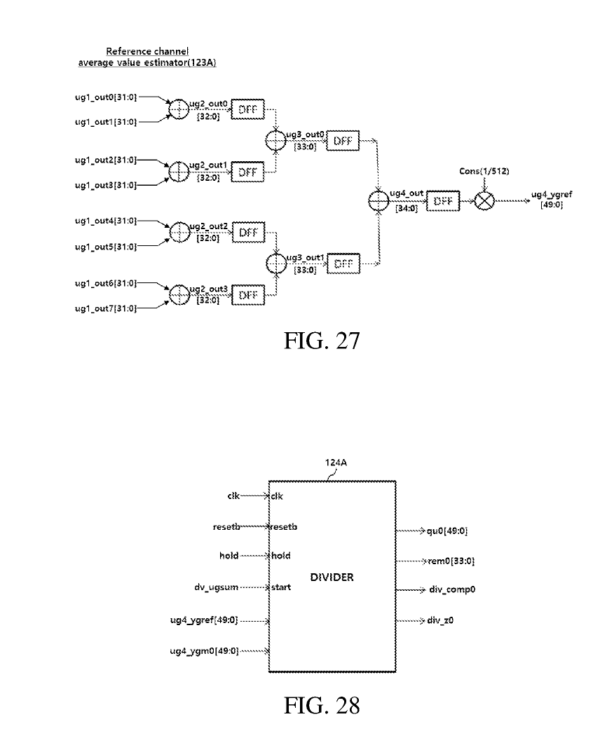

The square calculator 121A, the individual channel average value estimator 122A, the reference channel average value estimator 123A and the divider 124A is explained in details by referring to FIG. 24, FIG. 25, FIG. 26, FIG. 27 and FIG. 28 respectively.

The gain mismatch calibrator 120A comprises a gain buffer (not shown) similar to the offset mismatch calibrator 110A.

The offset calibrated digital samples for each channel are stored in the gain buffer without any data processing. The stored digital samples are used in the final process for calibrating the gain mismatch. Moreover, the gain buffer performs the same functions as the offset buffer 111A, and thus the detailed explanation of the gain buffer is not provided in the present invention.

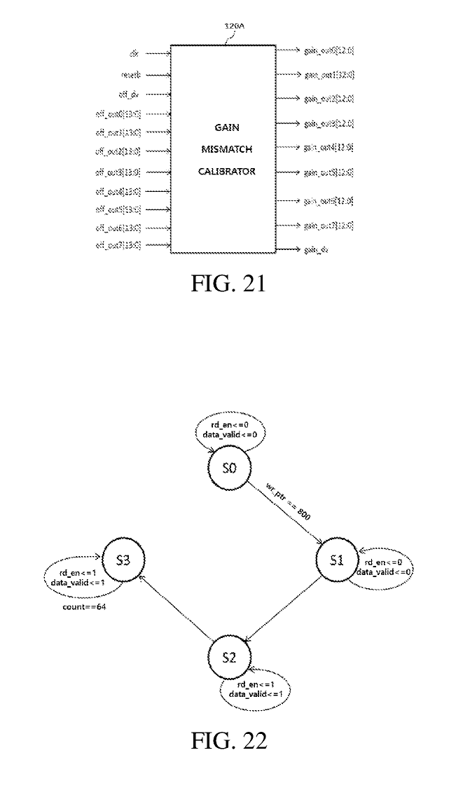

FIG. 22 is an exemplary view showing a state machine of the control logic for the gain mismatch calibrator in accordance with the preferred embodiment of the present invention.

As shown in FIG. 22, the state machine of control logic for the gain mismatch calibrator 120A takes the same roles as that of the offset mismatch calibrator 110A. The state machine controls two signals including read enable (rd_en) and data valid (data_valid) signals. The read enable (rd_en) signal is used for reading the value from the gain buffer. The data valid (data_valid) signal is used for synchronizing with the next operations after processing the data samples completed to calibrate the gain mismatch with the gain mismatch calibrator 120A. The initial state of the state machine is S0, and as soon as the write pointer (wr_ptr) reaches to 800, the corresponding state is reset or is changed into the next state. The write pointer (w_ptr) is used for writing the value in the gain buffer, and the wr_ptr counts as much as the depth (1024) of the gain buffer. Moreover, the write pointer (wr_ptr) increases by 8 for every clock after the count is started. S1 state and S2 state is commonly used for delay, and it is used for synchronizing with other calculations. The read enable (rd_en) signal and the data valid (data_valid) signal are kept high until state S2 is changed into state S3 and the system is reset or switched off. Since the read operation should be continuously operated for every clock, the state machine holds the state S3. The state S3 can simultaneously perform write operation as well as read operation.

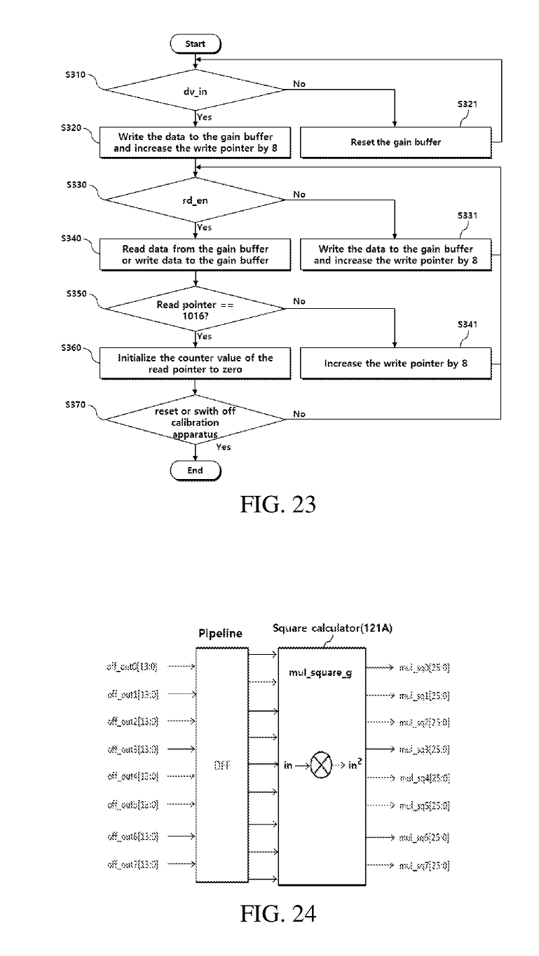

FIG. 23 is a flow diagram showing procedures performing read and write operations according to the gain buffer control logic in accordance with the preferred embodiment of the present invention.

As shown in FIG. 23, the procedures performing read and write operations, firstly write and store the offset calibrated data samples in the gain buffer at every clock when data valid (dv_in) signal is inputted from the offset mismatch calibrator 110A (S310), and increase the write pointer (wr_ptr) by 8 (S320). Meanwhile, when the data valid signal is not inputted (S310), the gain buffer is reset (S321).

Next, when the counter of the write pointer (wr_ptr) reaches to 800 the state machine makes the read enable (rd_en) signal high state (S330). And in this case, the gain mismatch calibrator 120A reads the digital samples per each channel from the gain buffer or writes the digital samples to the gain buffer (S340), and increases the read and write pointers by 8 at each clock.

When the read enable (rd_en) signal is not in high state (S330), the gain mismatch calibrator 120A continues the write operation, increases write pointer by 8 at each clock (S331), and waits until read enable (rd_en) signal that the state machine generates becomes high state. When the counter value of the read pointer reaches to 1016 (S350), the counter value of the read pointer is initialized to 0 (S360), and the read and write operations continue operations until the digital background calibration apparatus 100A is reset or switched off (S370).

FIG. 24 is a block diagram showing a square calculator in the gain mismatch calibrator in accordance with the preferred embodiment of the present invention.

The first process to perform calibration for gain in the gain mismatch calibrator 120A is squaring inputs for each channel. The square calculator 121A is pipelined for generating high speed data processing circuit based on 8 multipliers. Moreover, the bit width of the output for the square calculator 121A is 26-bit.

FIG. 25 and FIG. 26 are block diagrams showing an individual channel average value estimator in the gain mismatch calibrator in accordance with the preferred embodiment of the present invention.

In view of calculating the mismatch calibration in the offset mismatch calibrator 110A and the gain mismatch calibrator 120A, the calculations are similar in some parts. That is, both the offset mismatch calibrator 110A and the gain mismatch calibrator 120A require the sum of the digital samples of all channels for 512 digital samples and the sum of the digital samples for individual channel. The gain mismatch calibrator 120A performs the gain mismatch calibration by calculating average value of the calculated sum. However, the difference between the offset mismatch calibrator 110A and the gain mismatch calibrator 120A is that the sum of the gain mismatch calibrator 120A calculates the sum after squaring the digital samples inputted from each channel.

As shown in FIG. 25 and FIG. 26, the individual channel average value estimator 122A calculates the sum of 64 digital samples per each channel for the squared digital samples per each channel in the square calculator 121A, as the same procedures as performed in the offset mismatch calibrator 110A. The individual channel average value estimator 122A generates the sum (ug1_out0 to ug1_out7) per each channel at every 64 clock cycles by repeatedly calculating the sum using recursive registers per each channel until the counter reaches to 64. The individual channel average value estimator 122A calculates average value per each channel by multiplying the calculated sum per each channel by the prestored specific constant value (1/64). The specific constant value is stored as (19,18) fixed point format. Each average value per each channel is represented as the length of (50,24). It means the resultant has 24 fractional bits along with 26 decimal representing bits.

FIG. 27 is a block diagram showing a reference channel average value estimator in the gain mismatch calibrator in accordance with the preferred embodiment of the present invention.

As shown in FIG. 27, the reference channel average value estimator 123A calculates the average value of the sum (ug4_out) for the digital samples of all channels with inputting the output values of the square calculator 121A. That is, the reference channel average value estimator 123A calculates the average value of the reference channel by multiplying the sum by the stored specific constant value (1/512). The mechanism which calculates the sum is performed by the same mechanism as that performed in the reference channel offset estimator 112A of the offset mismatch calibrator 110A. The detailed explanations are not provided in the present invention.

FIG. 28 is a block diagram showing a divider in the gain mismatch calibrator in accordance with the preferred embodiment of the present invention.

As shown in FIG. 28, the divider 124A is designed by using Synopsys divider IP considering complexity of designing the digital background calibration apparatus 100A. The synopsys divider IP performs division operation according to the given number of clock, and the outputs comprise output valid signal, quotient and remainder. The divider 124A calculates the gain reference which acts as divisors to produce the gain mismatch corrected output and the result is very close to 1 but less than 1. According to the formula for Synopsys divider IP, in the case of each channel calculation, total 50-bit dividend which includes 24-bit fraction is needed and total 34-bit divisor which includes 8-bit fraction are needed. The Synopsys divider IP is instantiated for each channel and performs division operation for each channel. The inputs of the divider 124A comprise hold signal, start signal, divisor and dividend. The hold signal indicates whether to hold the result after calculation or not. When the hold signal is in high state, the result of the divider IP holds until the next divider IP calculation is completed.

Also dv_ugsum signal is the start signal for the divider after passing through synchronization delay, in which the dv_ugsum signal is generated from the individual channel average value estimator 122A. This signal must be high for one clock cycle to start the divider operation.

The dividend for each channel is generated from the individual channel average value estimator 122A, and the reference channel average value calculated in the reference channel average value estimator 123A becomes divisor, which divides the dividend. As the output of the divider 124A, the remainder (rem0) has the same bit width as the divisor, and the quotient (quo0) has the same bit width as the dividend. The divider 124A generates 20 unknown signals when the procedure is not completed. The divider 124A calculates the first channel quotient by dividing the first channel average value into the reference channel average value for calibrating the gain mismatch of the digital samples for each channel. The gain mismatch calculation for the rest of channels is performed by calculating quotient by dividing the average value for the rest of each channel into the first channel average value. The output of the divider 124A is fed to DFF, and the DFF outputs 19-bit ((19, 16) fixed point format) signal by truncating the 32 most significant bits of the output. The reason why truncating the output of the divider 124A is that the individual channel gain mismatch approaches the nearest value to 1 and is defined as range 0 to 5. Therefore, 3-bit provided for decimal side and 16-bit provided for fractional side are appropriate for further processing. Each channel quotient (quo0 to quo7) outputted from the divider 124A is used for the gain mismatch correction for each channel. Moreover, FIG. 28 is a block diagram showing division operations in the first channel of the plural channels, but the divider 124A is operated for the plurality of channels as explained above.

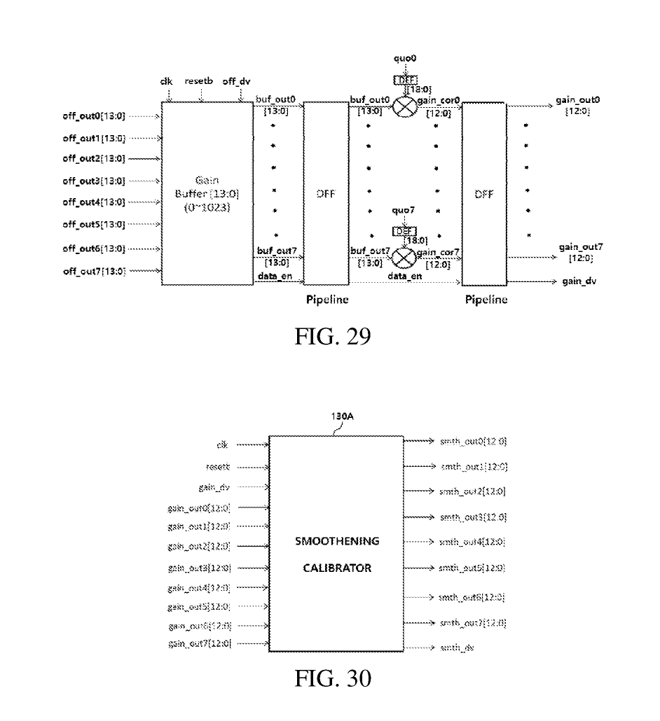

FIG. 29 is a block diagram showing the overall structure of the gain mismatch calibrator in accordance with the preferred embodiment of the present invention.

As shown in FIG. 29, outputs (quo0 to quo7) of the divider 124A are truncated through DFF and the truncated outputs of the divider 124A are used for the gain mismatch correction of the digital samples for each channel through the multiplier for each channel. The multiplier corrects the gain mismatch of the digital samples for each channel by taking the offset corrected digital samples for each channel as inputs from the gain buffer and by multiplying the quotients for each channel outputted from the divider 124A by the digital samples for each channel Outputs of each multiplier are the digital samples for each channel that the offset mismatch and gain mismatch are corrected. The fractional part of the outputs is truncated by DFF and the only decimal bits are produced with 13-bit.

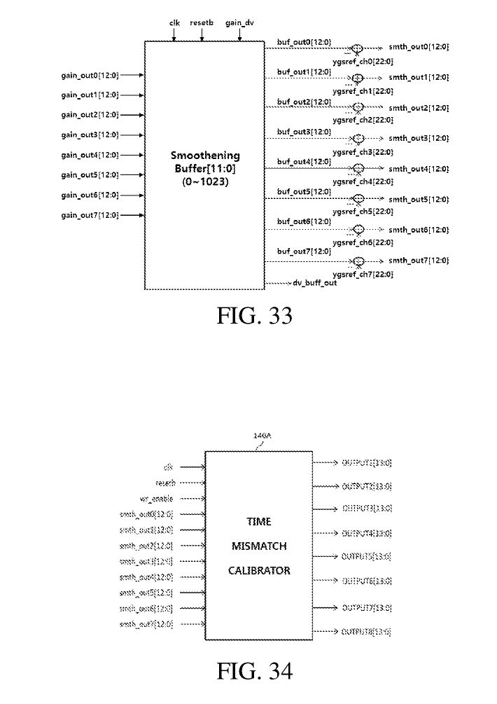

FIG. 30 to FIG. 33 are block diagrams showing the smoothening calibrator in accordance with the preferred embodiment of the present invention.

As shown in FIG. 30 to FIG. 33, the smoothening calibrator 130A removes spikes which can be generated in the process of correcting the gain mismatch in the gain mismatch calibrator 120A. The smoothening calibrator 130A comprises the smoothening buffer, and the smoothening buffer performs the same function as the offset buffer 111A with storing the digital samples for each channel being outputted from the gain mismatch calibrator 120A. The digital samples which the gain mismatch is corrected become the inputs of the smoothening calibrator 130A, which performs the same procedures and functions as the offset mismatch calibrator 110A. However, the word length of the digital samples in the offset mismatch calibrator 110A is different from that of the digital samples in the smoothening calibrator 130A, and the precision required for error correction is also different, thus the offset mismatch calibrator 110A is not reused. The smoothening calibrator 130A calculates the average value for each channel by averaging the sum of the digital samples for each channel, and calculates the average value of the reference channel for averaging the sum of the digital samples for all channels. The average value per channel is calculated by multiplying the specific constant value (1/65) to the respective sum per each channel, and the average value of the reference channel is calculated by multiplying the specific constant value (1/520) to the sum of the digital samples for all channels.

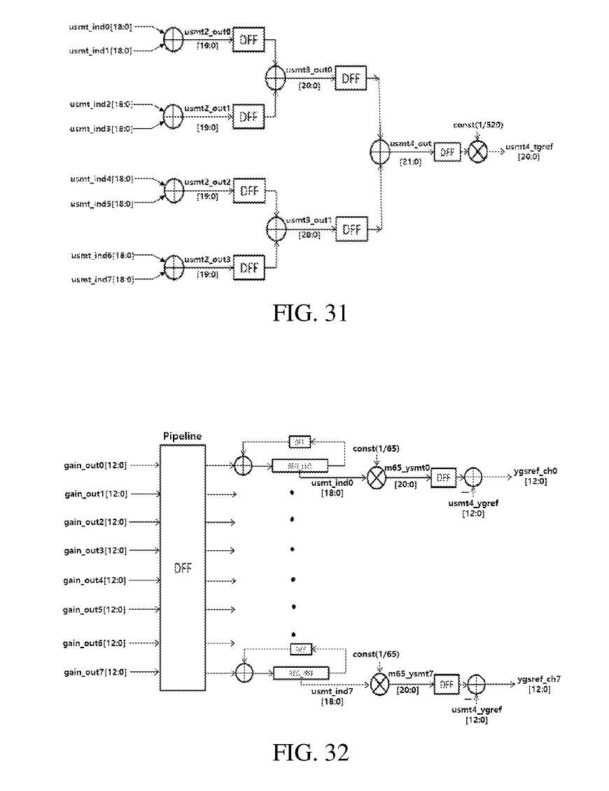

As shown in FIG. 31, the smoothening calibrator 130A calculates the average value for the reference channel through the specific constant value based multiplier with adding the digital samples for all channels where the gain mismatch is corrected. The calculation of average value for the reference channel is performed by the same procedure as the offset mismatch calibrator 110A, and thus the detailed descriptions are not provided.

As shown in FIG. 32, the smoothening calibrator 130A calculates average value for each channel by adding samples for each channel and through a multiplier based on specific constant value 1/65. By calculating the difference between the calculated average value for each channel and average value for the reference channel, the error for each channel caused by the spike can be calculated. The smoothening calibrator 130A reads the digital samples for each channel from the smoothening buffer, generates output signals (smth_out0 to smth_out7) and outputs them after correcting the error caused by the spike for each channel by subtracting the calculated spike error for each channel from the digital samples read for each channel. In the smoothening calibrator 130A, the procedures for correcting the error caused by the spike are performed by the same procedures as in the offset mismatch calibrator 110A. Thus, the detailed descriptions are not provided.

FIG. 34 is a block diagram showing a time mismatch calibrator in accordance with the preferred embodiment of the present invention.

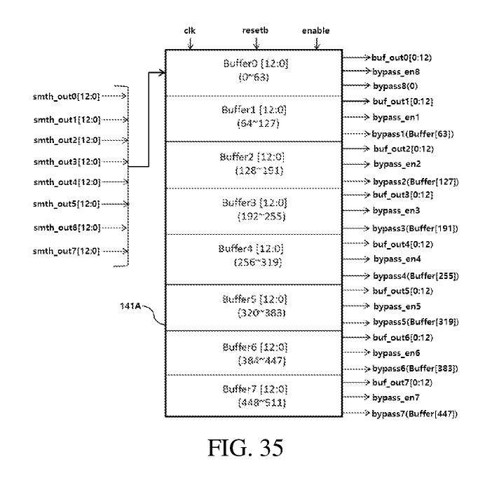

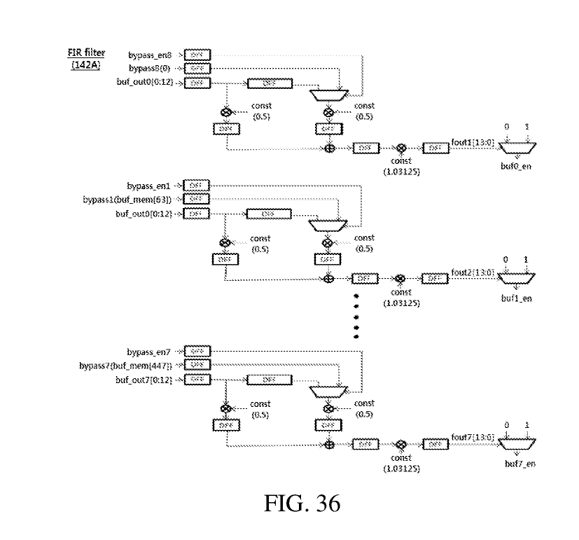

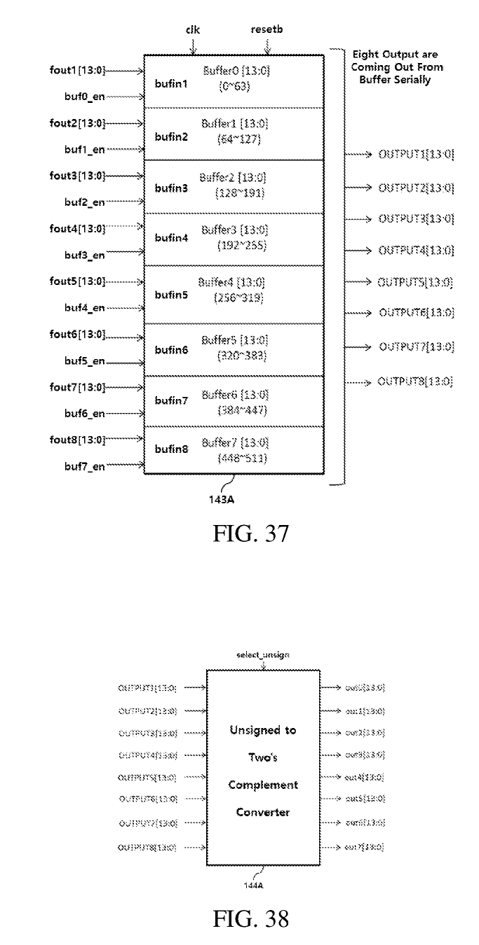

As shown in FIG. 34, the inputs of the time mismatch calibrator 140A are the digital samples for which the error caused by spike is corrected in the smoothening calibrator. The time mismatch calibrator 140A comprises input buffer 141A, FIR filter 142A, output buffer 143A and unsigned to two's complement converter 144A. The input buffer 141A, the FIR filter 142A, the output buffer 143A and unsigned to two's complement converter 144A are explained in details by referring to FIG. 35, FIG. 36, FIG. 37 and FIG. 38, respectively. The 1-bit wr_enable signal takes a role of notifying the point at which the time mismatch calibrator 140A starts to store the inputs in the input buffer 141A. The time mismatch calibrator 140A outputs the mismatch corrected digital samples (OUTPUT1 to OUTPUTS) for each channel by processing the inputted digital samples, and the outputs are 13-bit unsigned integer, which is provided to the two's complement converter 114A.

FIG. 35 is a block diagram showing the input buffer in the time mismatch calibrator in accordance with the preferred embodiment of the present invention.

As shown in FIG. 35, when the enable signal is present in the input buffer 141A, then the input buffer 141A starts to store the digital samples for each channel provided from the smoothening calibrator 130A. The input buffer 141A increases the counter value of write pointer by 8 for every storing operation, and the digital samples for each channel are continuously stored until reaching the final slot of the input buffer 141A. The depth of the input buffer 141A is 512 in length and 13-bit in width. After starting increment of the write pointer counter value, when the write pointer counter value reaches to 8, the input buffer 141A generates read_enable1 signal, and the read_enable1 signal results the output (buf_out1) of the input buffer 141A to the FIR filter 142A. Since the delay existing in the FIR filter 142A causes the signal distortion, The purposes of bypass_en and bypass signals that the input buffer 141A outputs are for replacing the first value of the FIR filter 142A with proper value.

When the write pointer value reaches 72, 136, 200, 264, 328, 392 and 456, the input buffer 141A transfers each digital sample stored in buffer1 to buffer7, each read_enable, bypass_enable, bypass signals to the corresponding FIR filter 142A, respectively.

FIG. 36 is a block diagram showing the FIR filter in the time mismatch calibrator in accordance with the preferred embodiment of the present invention.

As shown in FIG. 36, the FIR filter 142A is comprised by each channel (comprised by 8 filters in case of 8-channel TI-ADC), and the FIR filter comprised in the FIR filter 142A is a first order low pass filter. The input of the FIR filter is provided from the input buffer 141A, and the input is pipelined for high speed data processing. The FIR filter 142A makes the digital samples delayed by DFF after fetching the digital samples for each channel through filter coefficient 0.5-multiplier without any processing. At the same time, the FIR filter 142A fetches again the digital samples for each channel delayed by DEF using the filter coefficient multiplier after making digital samples for the each channel delayed first using DFF. Meanwhile the second fetch is multiplexed with 13-bit bypass signal, and the multiplexing is controlled by the bypass signal. At this moment, since the signals outputted by the FIR filter are being distorted by delay, so the output signals are corrected with bypass and bypass_en signals. The output for each channel which is filtered by the two filter coefficients multipliers is added by a adder, and the signals filtered for each channel are pipelined for avoiding the time mismatch after being multiplied with the specific constant value (1.03125) for resulting proper outputs. The final outputs (fout1 to fout8) of the FIR filter 142A are 14-bit in width, and provided to the output buffer 143A along with buffer valid signal buf_en0 to buf_en7 for each channel.

FIG. 37 is a block diagram showing the output buffer in the time mismatch calibrator in accordance with the preferred embodiment of the present invention.

As shown in FIG. 37, the depth of the output buffer 143A is 512 and 14-bit in width. The output buffer 143A starts to store the digital samples which are provided from the FIR filter 142A, when it receives the buffer valid signal from the FIR filter 142A. The each buffer enable signals (buf0_en to buf7_en) are present for part 0 to 7 of the output buffer 143A. When each buffer valid signal is received, the output buffer 143A increases write pointers for each part (write_pointer0 to write_pointer7) and stored for FIR filter 142A for each channel in order. The counter value of the write pointer increases from write_pointer0 to write_pointer7 in order. When the counter value of the write_pointer reaches 7, the output buffer 143A starts to output the stored samples. The output starts from buffer0, and the output buffer 143A controls the output using read counter. The read counter increases by 8 for each clock, and the output buffer 143A outputs the samples stored in buffer0 to buffer7 in order according to the read counter.

FIG. 38 is a block diagram showing the unsigned to 2's complement converter in the time mismatch calibrator in accordance with the preferred embodiment of the present invention. The overall processing of the time mismatch calibrator 140A is done by unsigned data (i.e., by positive integer).

As shown in FIG. 38, unsigned to 2's complement converter 144A is added in the output side of the digital background calibration apparatus 100A. The 14-bit final outputs (out0 to out7) are in 2's complement format by default. If the select_unsign signal is 1, the unsigned to two's complement converter 144A provides unsigned output.

As explained in the above descriptions, the present invention relating to a method and apparatus for digital background calibration in TI-ADCs reduces the hardware complexity and increases the efficiency of hardware resource. Wherein, the present invention uses the filter which has fixed filter coefficients, and thus has advantage of low complexity and high resource usage, since the present invention removes the necessity that plural LUTs have to be used in the existing technologies.

Moreover, the present invention only uses adders, shifters and multipliers for correcting the sampling time error, and thus has advantage of drastically reducing the time for correcting the sampling time error.

In addition, the present invention corrects the offset mismatch and the gain mismatch based on the statistical characteristics of the digital signals, and corrects the time mismatch based on FIR Filter, and thus the present invention has advantage of lowering hardware complexity and increasing the efficiency of hardware resource usage.

While the preferred embodiments of the present invention are mainly explained in the above descriptions, the technical idea of the present invention is not limited to the above description. That is, each component of the present invention can be changed or modified for achieving the same goals and effects as those of the present invention within the technical range of the present invention.

In addition, while the preferred embodiments of the present invention are shown and explained in the above figures and their descriptions, the present invention is not limited to the preferred specific embodiments which are explained above. Of course, a person who is skilled in the technical fields of the present invention can variously modify and transform the present invention without escaping the boundaries of the keypoints requested in the claims. And thus these modified implements should not be independently understood from the technical idea and respects of the present invention.

What is claimed is:

1. A method of processing digital background calibration for mismatches in M-channel time interleaved ADCs (TI-ADCs), comprising:
converting input analog signals to digital samples in each channel of time interleaved plurality of channels;
performing blind background calibration for offset and gain mismatches of the digital samples for the converted plurality of channels;
multiplexing digital samples for a plurality of blind background calibrated channels for the offset and gain; and
calibrating time mismatch for the multiplexed digital samples.

2. The method of claim 1, wherein performing the blind background calibration for the offset mismatch further comprises:
estimating the offset of reference channel by the mean value of samples outputted from the plurality of channels;
estimating the offset of each channel by the mean value of samples for each plurality of channels;
calculating offset error for each channel by calculating the difference value between the estimated offset for each channel and the offset of the reference channel; and
calibrating the offset of the samples for each channel by subtracting the calculated error for each channel from samples for each channel.

3. The method of claim 1, wherein performing the blind background calibration for the gain mismatch further comprises:
estimating the average power of reference channel by the mean square value for offset calibrated samples for a plurality of all channels;
estimating the average power for each channel by the mean square value for the samples of each offset calibrated channel;
calculating the error for the gain of the first channel by dividing the average power of the estimated first channel by the average power of the reference channel;
calculating the error for the gain of each remained channel by dividing the average power of each remained channel by the average power of the estimated first channel; and
calibrating the gain of the samples for each channel by dividing the samples of each offset calibrated channel by the error for the gain of the each calculated channel.

4. The method of claim 1, wherein calibrating the time mismatch further comprises:
calculating impulse response by using a derivative (or differential) filter for the multiplexed digital samples;
convolving the impulse response with the multiplexed digital samples;
calculating time delay by dividing the average value multiplying the convolved result by the multiplexed digital sample by mean square value of the convolved result;
calibrating time error by multiplying calculated time delay by the convolved result; and
calibrating the time delay by subtracting the calculated time error from the multiplexed digital sample.

5. The method of claim 1, wherein calibrating the time mismatch further comprises:
calibrating phase and amplitude of the digital sample by using micro delay filter and scaling factor for the time delay calibrated digital sample.

6. An apparatus of digital background calibration for mismatches in M-channel time interleaved ADCs (TI-ADCs), comprising:
an ADC bank is configured to convert input analog signals to digital samples in each channel of time interleaved plurality of channels;
a blind background calibrator coupled to the ADC bank and configured to perform blind background calibration for offset and gain mismatches of the digital samples for the converted plurality of channels;
a multiplexer coupled to the blind background calibrator and configured to multiplex the digital samples for a plurality of blind background calibrated channels calibrated in the blind background calibrator for the offset and gain; and
a time mismatch calibrator coupled to the multiplexer and configured to calibrate time delay for the multiplexed digital samples in the multiplexer.

7. The apparatus of claim 6, wherein the blind background calibrator further comprising:
a reference channel estimator configured to estimate the offset of reference channel by the mean value of samples outputted from the plurality of channels;
an individual channel estimator configured to estimate the offset of each channel by the mean value of samples for each plurality of channels;
an error calculator coupled to the reference channel estimator and individual channel estimator, and configured to calculate offset error for each channel by calculating the difference value between the estimated offset for each channel and the offset of the reference channel; and
a channel error calibrator coupled to the error calculator and configured to calibrate the offset of the samples for each channel by subtracting the calculated error for each channel from samples for each channel.

8. The apparatus of claim 7, wherein the reference channel estimator further configured to estimate the average power of reference channel by the mean square value for offset calibrated samples for a plurality of all channels;
the individual channel estimator further configured to estimate the average power for each channel by the mean square value for the samples of each offset calibrated channel;
the error estimator further configured to calculate the error for the gain of the first channel by dividing the average power of the estimated first channel by the average power of the reference channel, and calculating the error for the gain of each remained channel by dividing the average power of each remained channel by the average power of the estimated first channel; and
the channel error calibrator further configured to calibrate the gain of the samples for each channel by dividing the samples of each offset calibrated channel by the error for the gain of each calculated channel.

9. The apparatus of claim 6, wherein the time mismatch calibrator further configured to:
calculate impulse response by using a derivative (or differential) filter for the multiplexed digital samples;
convolve the impulse response with the multiplexed digital samples;
calculate time delay by dividing the average value multiplying the convolved result by the multiplexed digital sample by mean square value of the convolved result;
calibrate time error by multiplying calculated time delay by the convolved result; and
calibrate the time delay by subtracting the calculated time error from the multiplexed digital sample.

10. The apparatus of claim 9, wherein the time mismatch calibrator further comprising:
an error scalier configured to calibrate phase and amplitude of the digital sample by using micro delay filter and scaling factor for the time delay calibrated digital sample.

11. An apparatus of digital background calibration for mismatches in time interleaved ADCs (TI-ADCs) comprising:
an offset mismatch calibrator configured to calibrate offset mismatch for the result of TI-ADC with at least more than two channels; and
a gain mismatch calibrator coupled to the offset mismatch calibrator and configured to calibrate gain mismatch for the offset calibrated digital sample.

12. The apparatus of claim 11, wherein the apparatus further comprising:
a smoothening calibrator configured to calibrate spike (extra high frequency tone) occurring in the course of calibrating the gain mismatch; and
a time mismatch calibrator coupled to the smoother and configured to calibrate time mismatch for the spike calibrated digital sample.

13. The apparatus of claim 11, the offset mismatch calibrator further comprising:
an offset buffer configured to store the digital sample for a plurality of channels;
a reference channel offset estimator coupled to the offset buffer and configured to estimate offset of reference channel by calculating the average value for the sum of digital samples outputted from the offset buffer; and
an individual channel offset estimator coupled to the offset buffer and configured to estimate offset of individual channel by calculating the average value of digital samples for a plurality of channels outputted from the offset buffer.

14. The apparatus of claim 13, wherein the offset mismatch calibrator further configured to:
calculate offset mismatch for each channel by calculating the difference value between the offset of the estimated individual channel and the offset of the reference channel; and
calibrate offset mismatch for the digital sample of each channel by subtracting the calculated offset mismatch for each channel from the plurality of digital samples for each channel.

15. The apparatus of claim 11, wherein the gain mismatch calibrator further comprising:
a gain buffer configured to store digital samples for the offset calibrated plurality of channels,
a square calculator configured to calculate square value of the samples for each channel outputted from the gain buffer;
a reference channel average value estimator configured to calculate the average value for the plurality of digital samples outputted from the square calculator; and
an individual channel average value estimator configured to calculate the average sum of the samples for each channel outputted from the square calculator.

16. The apparatus of claim 15, wherein the gain mismatch calibrator further configured to:
calculate the quotient by dividing the average value of the first channel among the plurality of channels by the average value of the reference channel;
calibrate the gain mismatch for the digital samples of the first channel by multiplying the digital sample of the first channel by the calculated quotient;
calculate the quotient for each channel by dividing the average value for each remained channel excepting for the first channel by the average value of the first channel; and
calibrate the gain mismatch of the digital samples for each channel by multiplying the digital samples for each channel by the quotient of each channel.

17. The apparatus of claim 12, wherein the smoothening calibrator further configured to:
calculate the average value for the reference channel by averaging the sum of the digital samples for the plurality of channels outputted from the smoothening buffer, which stores the digital samples for the gain calibrated plurality of channels; and
calculate the average value of each channel by averaging the sum of the digital samples for each channel outputted from the smoothening buffer.

18. The apparatus of claim 17, wherein the smoothening calibrator further configured to:
calculate the spike error for each channel by calculating the difference value between the average value of the calculated average value for each channel and the average value of the reference channel; and
calibrate the spike error for the digital samples of each channel by subtracting the calculated spike error for each channel from the digital samples of each channel.

19. The apparatus of claim 12, wherein the time mismatch calibrator further comprising:
an input buffer configured to store by channel the spike error calculated digital samples for the plurality of channels;
an FIR filter configured to calibrate time delay mismatch for the digital samples; and
an output buffer configured to output the digital samples outputted from the FIR filter.

20. The apparatus of claim 19, wherein the FIR filter configured to comprise by each channel a first order FIR low pass filter for the digital samples of the plurality of channels.
